(19) United States
(12) Patent Application Publication
(10) Pub. No.: US 2025/0329625 A1
(43) Pub. Date: Oct. 23, 2025

(54) CIRCUIT BOARD AND SEMICONDUCTOR PACKAGE COMPRISING SAME

(71) Applicant: LG INNOTEK CO., LTD., Seoul (KR)

(72) Inventors: Dong Sun KIM, Seoul (KR); Sang Hyuck NAM, Seoul (KR)

(73) Assignee: LG INNOTEK CO., LTD., Seoul (KR)

(21) Appl. No.: 18/870,312

(22) PCT Filed: Jun. 7, 2023
(86) PCT No.: PCT/KR2023/007789

§ 371 Date: Nov. 27, 2024

(30) Foreign Application Priority Data
Jun. 7, 2022 (KR) 10-2022-0068943

(51) Int. Cl. H01L 23/498; H01L 23/00

(52) U.S. Cl. CPC H01L 23/49838; H01L 23/564

(57) ABSTRACT

A circuit board according to an embodiment includes an insulating layer including an upper surface and a lower surface, and having a recess concave from the upper surface toward the lower surface; and a circuit pattern layer disposed in the recess of the insulating layer, wherein the circuit pattern layer includes a first circuit pattern part and a second circuit pattern part spaced apart in a horizontal direction, at least a portion of an upper surface of the first circuit pattern part is positioned lower than the upper surface of the insulating layer and an upper surface of the second circuit pattern part, and the upper surface of the second circuit pattern part is positioned lower than the upper surface of the insulating layer.

### TECHNICAL FIELD

An embodiment relates to a circuit board and a semiconductor package comprising the same.

### BACKGROUND ART

A circuit board includes an insulating layer and a circuit pattern disposed on the insulating layer. A circuit board refers to a board before a semiconductor device is mounted. In other words, a circuit board refers to a circuit pattern disposed on an insulating layer to determine a mounting location of each semiconductor device in order to mount at least one semiconductor device. The semiconductor device is mounted on the circuit board and can transmit and receive signals through the circuit pattern.

Meanwhile, with the recent advancement of portable electronic devices, etc., the frequency of signals is increasing in order to process a large amount of information at high speed, and a circuit board suitable for high-frequency applications is required.

Such a circuit board enables signal transmission in an integrated state while minimizing signal transmission loss. To this end, miniaturization of the circuit pattern included in the circuit board is required.

Meanwhile, an amount of data processing is rapidly increasing due to technological advancement. In response to this, a semiconductor package is required to have high input/output for high performance and a small or slim form-factor structure.

In addition, the circuit board is manufactured using the ETS (Embedded Trace Substrate) method that enables the implementation of a fine circuit pattern to satisfy the requirements. The ETS method refers to a manufacturing method that embeds the circuit pattern in an insulating layer, and is advantageous in miniaturizing the circuit pattern because there is no circuit loss due to etching.

Accordingly, the circuit board used for mounting an AP (Application Processor) chip is manufactured using the ETS method.

At this time, a circuit pattern of a region where the AP chip is mounted on the circuit board is a fine pattern, and thus, a problem occurs in which a SR (Solder Resist) cannot be disposed in the region. As a result, in a soldering process for mounting the AP chip, electrical reliability problems such as a circuit short are occurring due to the flow of a solder.

### DISCLOSURE

### Technical Problem

The embodiment provides a circuit board having a novel structure and a semiconductor package including the same.

In addition, the embodiment provides a circuit board having improved electrical reliability and a semiconductor package including the same.

In addition, the embodiment provides a circuit board capable of solving a circuit short problem occurring in an open region of a protective layer and a semiconductor package including the same.

In addition, the embodiment provides a circuit board capable of preventing overflow of a connecting member and a semiconductor package including the same.

In addition, the embodiment provides a circuit board capable of being slimmed down and a package substrate including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer including an upper surface and a lower surface, and having a recess concave from the upper surface toward the lower surface; and a circuit pattern layer disposed in the recess of the insulating layer, wherein the circuit pattern layer includes a first circuit pattern part and a second circuit pattern part spaced apart in a horizontal direction, wherein at least a portion of an upper surface of the first circuit pattern part is positioned lower than the upper surface of the insulating layer and an upper surface of the second circuit pattern part, and wherein the upper surface of the second circuit pattern part is positioned lower than the upper surface of the insulating layer.

In addition, the first circuit pattern part includes a first electrode and a second electrode spaced apart in the horizontal direction, and a height of an upper surface of the first electrode is different from a height of an upper surface of the second electrode.

In addition, the second circuit pattern part includes a third electrode, and the height of the upper surface of the first electrode is different from a height of an upper surface of the third electrode.

In addition, the upper surface of the first electrode is positioned lower than each of the upper surface of the second electrode and the upper surface of the third electrode.

In addition, the height of the upper surface of the second electrode is same as the height of the upper surface of the third electrode.

In addition, the height of the upper surface of the second electrode is different from the height of the upper surface of the third electrode, and a vertical distance from the upper surface of the second electrode to the upper surface of the third electrode is smaller than a vertical distance from the upper surface of the first electrode to the upper surface of the second electrode, and a vertical distance from the upper surface of the first electrode to the upper surface of the third electrode.

In addition, the vertical distance from the upper surface of the insulating layer to the upper surface of the second electrode or the upper surface of the third electrode satisfies a range of 2 um to 5 um.

In addition, the vertical distance from the upper surface of the insulating layer to the upper surface of the first electrode satisfies a range of 5 um to 18 um.

In addition, the first electrode is a first pad on which a terminal of a semiconductor device is mounted, the second electrode is a trace connected to at least one of the first electrode and the third electrode, and the third electrode is a second pad connected to an external substrate.

In addition, the first electrode is a first pad of a dummy electrode to which a semiconductor device is attached.

In addition, the second electrode is a bonding electrode connected to a terminal of the semiconductor device attached to the first electrode, and the third electrode is a second pad connected to an external substrate.

In addition, a width in a horizontal direction of the first electrode is larger than a width in the horizontal direction of the second electrode.

In addition, a width in the horizontal direction of the third electrode is larger than the width in the horizontal direction of each of the first electrode and the second electrode.

In addition, lower surfaces of each of the first to third electrodes are located on the same plane.

In addition, a thickness in a vertical direction of the first electrode is different from a thickness in the vertical direction of the second electrode and A thickness in the vertical direction of the third electrode.

In addition, the thickness in the vertical direction of the first electrode is smaller than the thickness in the vertical direction of the second electrode and the thickness in the vertical direction of the third electrode.

In addition, the circuit board further includes a protective layer disposed on the insulating layer and having an opening overlapping the circuit pattern layer in the vertical direction.

In addition, the opening of the protective layer includes a first opening overlapping the first electrode and the second electrode in the vertical direction as a whole.

In addition, the opening of the protective layer includes a second opening partially overlapping the third electrode in the vertical direction.

Meanwhile, a semiconductor package according to an embodiment comprises: a first insulating layer including a first region and a second region separated from the first region in a horizontal direction; a first circuit pattern layer including a first pattern part disposed on the first region of the first insulating layer and a second pattern part disposed on the second region of the insulating layer; and a first protective layer disposed on the first insulating layer and including a first opening overlapping the first region in the vertical direction as a whole and a second opening partially overlapping the second region in the vertical direction; and a first chip disposed on the first pattern part; wherein the first pattern part includes a first-first pattern and a first-second pattern, the second pattern part includes a second pattern, the first chip is disposed on the first-first pattern of the first pattern part, the first-first pattern includes a first recess that is concave from an upper surface of the first-first pattern toward a lower surface of the first-first pattern, the first-second pattern includes a second recess that is concave from an upper surface of the first-second pattern toward a lower surface of the first-second pattern, the second pattern includes a third recess that is concave from an upper surface of the second pattern toward a lower surface of the second pattern, and a depth of the first recess is greater than a depth of the second recess and a depth of the third recess.

In addition, the first-first pattern is a first pad on which the first chip is mounted, the first-second pattern is a trace connected to at least one of the first pad and the second pattern, wherein the semiconductor package further comprises a first connecting part disposed on the first pad, and the first chip includes a terminal disposed on the first connecting part and disposed in the first recess.

In addition, the first-first pattern is a first pad of a dummy pattern to which the first chip is attached, the first-second pattern is a bonding pattern connected to the terminal of the first chip, wherein the semiconductor package further comprises an adhesive member disposed on the first pad; and a connecting member connecting between the terminal of the first chip and the bonding pattern, and at least a portion of the first chip is disposed in the first recess.

In addition, the semiconductor package includes a bump disposed on the second pattern; a molding layer molding the bump and the first chip; and an external substrate disposed on the bump and including a second chip, and the molding layer is formed to fill the second recess of the first-second pattern.

In addition, the first chip includes at least one logic chip, and the second chip includes a memory chip.

### Advantageous Effects

The embodiment can improve electrical reliability and physical reliability of a circuit board and a semiconductor package including the same.

The circuit board of the embodiment includes a first insulating layer, a first circuit pattern layer, and a first protective layer. At this time, the first insulating layer means an outermost insulating layer among a plurality of insulating layers of the circuit board. The first circuit pattern layer means an outermost circuit pattern layer among a plurality of circuit pattern layers of the circuit board. At this time, the first circuit pattern layer has an ETS structure. For example, the first circuit pattern layer is embedded in an upper surface of the first insulating layer.

At this time, the upper surface of the first circuit pattern layer has a step difference with the upper surface of the first insulating layer. Specifically, the upper surface of the first circuit pattern layer is positioned lower than the upper surface of the first insulating layer. The first circuit pattern layer includes a fine pattern. The fine pattern may be damaged by various factors in a manufacturing process and an usage environment of the circuit board. At this time, the embodiment allows the upper surface of the first circuit pattern layer to be positioned lower than the upper surface of the first insulating layer. Accordingly, the embodiment can stably protect the first circuit pattern layer from the damage. Therefore, the embodiment can solve a peeling problem or collapse problem of the first circuit pattern layer. Through this, the embodiment can improve the physical reliability and electrical reliability of the circuit board and the semiconductor package.

Meanwhile, the first circuit pattern layer can be divided into a plurality of pattern parts according to a location. That is, the first circuit pattern layer includes a first pattern part disposed in a first region where a chip is mounted and a second pattern part disposed in a second region other than the first region. The first protective layer is not disposed on the first region. In other words, the first protective layer includes a first opening that vertically overlaps the first region as a whole.

At this time, the first pattern part includes a first pad and a trace that second pad that vertically overlaps the second opening. At this time, the upper surface of the first pad can have a step difference from the upper surface of the trace and the upper surface of the second pad. That is, the upper surface of the first pad may be positioned lower than the upper surface of the trace and the upper surface of the second pad. In other words, a first recess may be formed on the upper surface of the first pad, a second recess may be formed on the upper surface of the trace, and a third recess may be formed on the upper surface of the second pad. In addition, a depth of the first recess may be greater than each of depths of the second recess and the third recess.

At this time, the first pad is a mounting pad on which a chip is mounted, and a connecting part such as solder is disposed on the upper surface of the first pad. At this time, the first protective layer is not disposed on the first region where the first pad is disposed, and thus overflow of the connecting part may occur. Accordingly, the embodiment allows the upper surface of the first pad to be positioned lower than the trace and the upper surface of the second pad, thereby securing a space for arranging the connecting part without increasing the overall thickness of the circuit board.

Accordingly, the embodiment can prevent diffusion of the connecting part and solve the circuit short problem caused by diffusion of the connecting part.

Meanwhile, the first circuit pattern layer in the embodiment includes a first pad, which is a dummy pattern, and a bonding pattern. In addition, a chip can be attached to the first pad. In addition, the bonding pattern can be connected to the chip through a connecting member such as a wire. At this time, a first recess is formed on the first pad, and a second recess is formed on the bonding pattern. In addition, a depth of the first recess can be greater than a depth of the second recess. The first recess can function as a cavity into which the chip is inserted.

Accordingly, the embodiment can lower a height at which the chip is disposed by a depth of the first recess. Therefore, the embodiment can reduce the overall thickness of the circuit board and the semiconductor package.

### DESCRIPTION OF DRAWINGS

FIG. 1 is a cross-sectional view of a semiconductor package according to a first comparative example.

FIG. 2 is a cross-sectional view of a semiconductor package according to a second comparative example.

FIG. 3 is a cross-sectional view of a circuit board according to a first embodiment.

FIG. 4 is an enlarged plan view of a partial region of a first circuit pattern layer.

FIG. 5 is an enlarged cross-sectional view of a partial region of a first circuit pattern layer of FIG. 3.

FIG. 6 is a drawing for explaining a layer structure of the first circuit pattern layer of FIG. 3.

FIG. 7 is a drawing showing a circuit board according to a second embodiment.

FIG. 8 is an enlarged view of a partial region of FIG. 7.

FIG. 9 is a drawing showing a semiconductor package according to a first embodiment.

FIG. 10 is an enlarged view of a chip arrangement region of FIG. 9.

FIG. 11 is a drawing showing a semiconductor package according to a second embodiment.

FIGS. 12 to 25 are cross-sectional views showing a manufacturing method of a circuit board illustrated in FIG. 3 in order of processes.

### BEST MODE

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between,” “adjacent” versus “directly adjacent,” etc.).

As used herein, the singular forms “a,” “an” and “the” are intended to include the plural forms as well, unless the context clearly indicates otherwise.

It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Hereinafter, an embodiment of the present invention will be described in detail with reference to the attached drawings.

### Comparative Example

Before explaining the embodiments of the present invention, the problems of comparative examples will be explained.

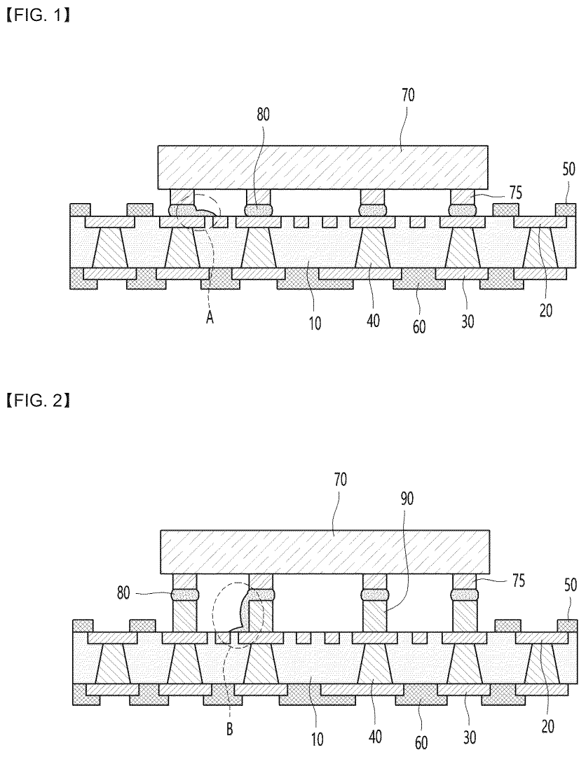

FIG. 1 is a cross-sectional view of a semiconductor package according to a first comparative example, and FIG. 2 is a cross-sectional view of a semiconductor package according to a second comparative example.

Referring to FIGS. 1 and 2, the circuit board according to the first and second comparative examples includes an insulating layer 10.

In addition, a first circuit pattern layer 20 is disposed on an upper surface of the insulating layer 10. In addition, a second circuit pattern layer 30 is disposed on the lower surface of the insulating layer 10.

At this time, the circuit pattern layer of the circuit board is required to be miniaturized. Accordingly, the circuit board has an ETS (Embedded Trace Substrate) structure that is advantageous for miniaturizing the circuit pattern layer. Therefore, the first circuit pattern layer 20 has a structure embedded in an upper surface of the insulating layer 10.

In addition, a through electrode 40 penetrates the insulating layer 10. The through electrode 40 electrically connects the first circuit pattern layer 20 and the second circuit pattern layer 30.

In addition, a first protective layer 50 is disposed on the upper surface of the insulating layer 10. In addition, the second protective layer 60 is disposed on the lower surface of the insulating layer 10.

At this time, the first protective layer 50 and the second protective layer 60 include an open region (SRO). The open region (SRO) is formed by exposing and developing the first protective layer 50 and the second protective layer 60.

At this time, there is a limitation on a size of the open region (SRO) that can be formed in the first protective layer 50 and the second protective layer 60. For example, the open region (SRO) has a width of at least 40 um or more. This is due to the process capability in the exposure process of the first protective layer 50 and the second protective layer 60.

Here, the first circuit pattern layer 20 includes a pad (not shown) on which a chip 70 is disposed and a trace (not shown) connected to the pad. The pad and the trace are fine-patterns connected to the chip 70. For example, a line width and a spacing of the trace are 12 um or less, 10 um or less, or 5 um or less.

Accordingly, it is difficult to form an open region (SRO) of the first protective layer 50 in a mounting region where the pad and trace connected to the chip 70 are disposed among the upper surface region of the insulating layer 10. Here, the open region means an opening corresponding 1:1 to one pad in the first protective layer 50. Therefore, the first protective layer 50 has a structure that opens the mounting region as a whole (for example, a structure that is not disposed in the mounting region).

Meanwhile, a chip 70 is disposed in the mounting region. The chip 70 includes a processor chip. The chip 70 includes a chip bump 75 corresponding to a terminal on the lower surface. In addition, the chip 70 is attached and fixed on the first circuit pattern layer 20 of the mounting region through a connecting part 80. The connecting part 80 is a solder disposed between the chip bump 75 and the first circuit pattern layer 20.

In the first comparative example of FIG. 1, the connecting part 80 has a structure in which it is disposed between the first circuit pattern layer 20 and the chip bump 75. At this time, the first protective layer 50 is not disposed around the first circuit pattern layer 20 in which the connecting part 80 is disposed. For example, the first protective layer 50 has an open region wholly opening the mounting region. Therefore, the upper surface of the pads and traces disposed in the mounting region has a structure in which they are exposed to an upper side of the circuit board. Accordingly, in the first comparative example, solder diffusion proceeds in a soldering process using the connecting part 80. Accordingly, the first comparative example has a problem that a circuit short occurs due to the diffusion of the solder, such as in the ‘A’ region of FIG. 1, in which the connecting part 80 comes into contact with another neighboring pad or trace.

At this time, as in the second comparative example of FIG. 2, in the second comparative example, a bump 90 is disposed on the pad of the first circuit pattern layer 20 of the mounting region. In addition, the connecting part 80 is disposed on the bump 90. However, the connecting part 80 is spread along a side surface of the bump 90. In addition, the solder spread along the side surface of the bump 90 is connected to another neighboring pad or trace, such as in a ‘B’ region of FIG. 2.

In addition, in the second comparative example, in order to prevent the diffusion of the solder in the structure in which the bump 90 is disposed, a first protective layer 50 having a thin thickness is formed on the mounting region. In a case of arranging the first protective layer 50 in the above-mentioned mounting region, the circuit short problem can be solved, but there is a problem that the manufacturing process becomes complicated. In addition, the upper surface of the pad may be covered with the first protective layer 50 according to the process capability in a process of forming the open region, which may cause a problem in electrical connection with the chip 70.

In addition, recent electric/electronic products are becoming more high-performance, and accordingly, technologies for attaching a larger number of packages to a limited-size substrate are being studied. In addition, functions processed in the application processor (AP) are increasing, and accordingly, a number of terminals of the processor chip is increasing. Accordingly, the circuit pattern layer disposed in the mounting region is required to be ultra-fine. In addition, at least two processor chips are required to be mounted on one circuit board due to the increase in the functions. Accordingly, it is becoming more difficult to dispose the first protective layer 50 in the mounting region. Accordingly, a technology that can solve the circuit short problem in the mounting region is required.

### —Electronic Device—

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. At least one chip may be mounted in the semiconductor package. The semiconductor package may mount memory chips such as volatile memory (e.g., DRAM), non-volatile memory (e.g., ROM), and flash memory, application processor chips such as a central processor (e.g., CPU), a graphic processor (e.g., GPU), a digital signal processor, an encryption processor, a microprocessor, and a microcontroller, and logic chips such as an analog-to-digital converter and an ASIC (application-specific IC).

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Below, a circuit board and a semiconductor package including the same according to an embodiment will be described.

### —Circuit Board—

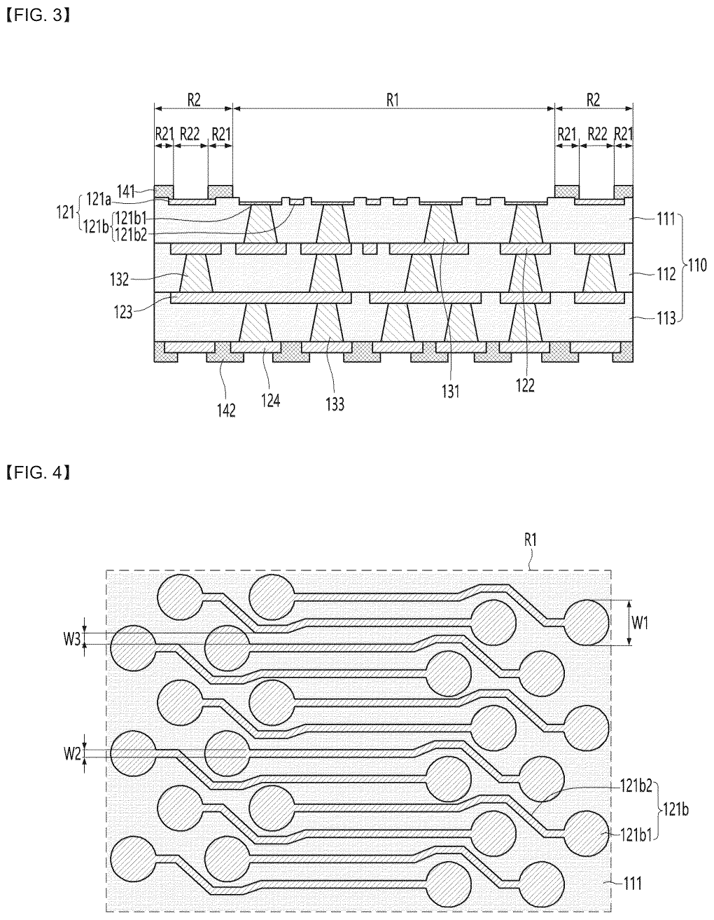

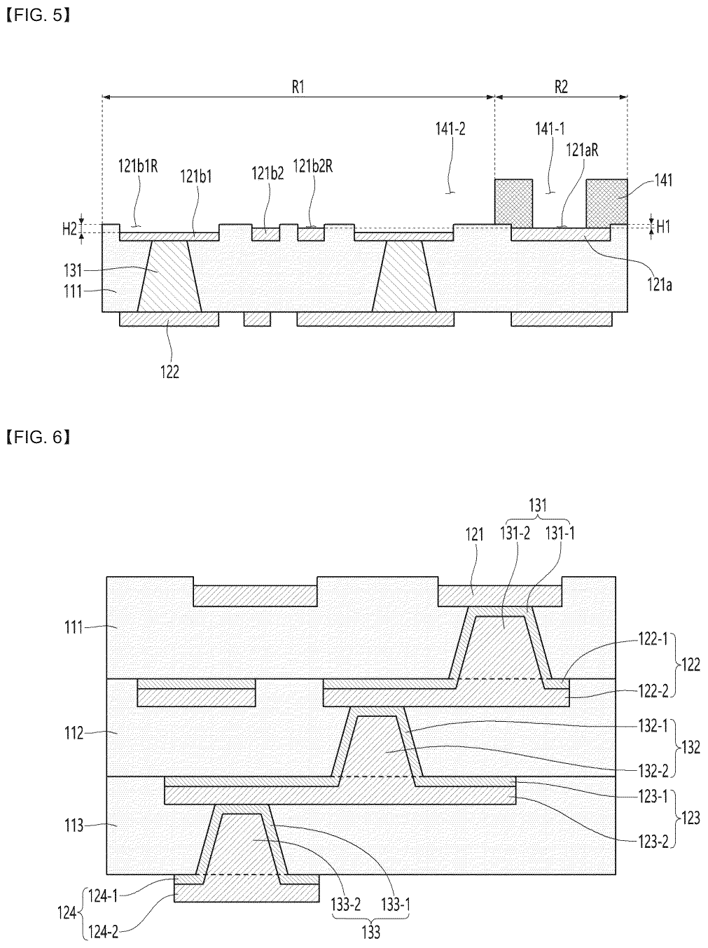

FIG. 3 is a cross-sectional view of a circuit board according to a first embodiment, FIG. 4 is an enlarged plan view of a partial region of a first circuit pattern layer, FIG. 5 is an enlarged cross-sectional view of a partial region of a first circuit pattern layer of FIG. 3, and FIG. 6 is a drawing for explaining a layer structure of the first circuit pattern layer of FIG. 3.

Hereinafter, a circuit board according to a first embodiment will be specifically described with reference to FIGS. 3 to 6.

The circuit board of the embodiment provides a mounting space in which at least one chip can be mounted.

For example, the circuit board of the embodiment may provide a mounting space in which one chip is mounted, or alternatively, may provide multiple mounting spaces in which two or more chips are mounted.

In addition, one processor chip may be mounted on the circuit board. In addition, at least two processor chips having different functions may be mounted on the circuit board. In addition, one processor chip and one memory chip may be mounted on the circuit board. In addition, two or more processor chips having different functions and one or more memory chips may be mounted on the circuit board.

The circuit board includes an insulating layer 110. The insulating layer 110 may have at least one layer.

At this time, in FIG. 3, the circuit board is illustrated as including three insulating layers, but it is not limited thereto.

For example, the circuit board may include two or fewer insulating layers, or alternatively, may include four or more insulating layers.

However, for convenience of explanation, the circuit board will be described below as including three insulating layers.

The insulating layer 110 may include a first insulating layer 111, a second insulating layer 112, and a third insulating layer 113.

At least one of the first insulating layer 111, the second insulating layer 112, and the third insulating layer 113 may be rigid or flexible. For example, at least one of the first insulating layer 111, the second insulating layer 112, and the third insulating layer 113 may include glass or plastic. For example, at least one of the first insulating layer 111, the second insulating layer 112, and the third insulating layer 113 may include chemically strengthened/semi-strengthened glass such as soda lime glass or aluminosilicate glass. For example, at least one of the first insulating layer 111, the second insulating layer 112, and the third insulating layer 113 may include a strengthened or flexible plastic such as polyimide (PI), polyethylene terephthalate (PET), propylene glycol (PPG), or polycarbonate (PC). For example, at least one of the first insulating layer 111, the second insulating layer 112, and the third insulating layer 113 may include sapphire. For example, at least one of the first insulating layer 111, the second insulating layer 112, and the third insulating layer 113 may include an optically isotropic film. For example, at least one of the first insulating layer 111, the second insulating layer 112, and the third insulating layer 113 may include a cyclic olefin copolymer (COC), a cyclic olefin polymer (COP), an optically isotropic polycarbonate (PC), or an optically isotropic polymethyl methacrylate (PMMA). For example, at least one of the first insulating layer 111, the second insulating layer 112, and the third insulating layer 113 may be formed of a material including an inorganic filler and an insulating resin. For example, at least one of the first insulating layer 111, the second insulating layer 112, and the third insulating layer 113 may have a structure in which an inorganic filler of silica or alumina is disposed in a thermosetting resin or a thermoplastic resin. For example, at least one of the first insulating layer 111, the second insulating layer 112, and the third insulating layer 113 may use ABF (Ajinomoto Build-up Film), FR-4, BT (Bismaleimide Triazine), PID (Photo Imageable Dielectric resin), BT, etc. For example, at least one of the first insulating layer 111, the second insulating layer 112, and the third insulating layer 113 may include RCC (Resin coated copper).

The first insulating layer 111 may be a first outer insulating layer of a circuit board. For example, the first insulating layer 111 may be an insulating layer disposed at an uppermost side among a plurality of insulating layers. The second insulating layer 112 may be an inner insulating layer of the circuit board. For example, the second insulating layer 112 may be an intermediate insulating layer disposed between a first outer insulating layer and a second outer insulating layer. For example, the third insulating layer 113 may be a second outer insulating layer. For example, the third insulating layer 113 may be an insulating layer disposed at a lowermost side among a plurality of insulating layers.

At this time, when the circuit board of the embodiment includes one insulating layer, the insulating layer 110 may include only the first insulating layer 111. For example, when the circuit board of the embodiment includes two insulating layers, the insulating layer 110 may include the first insulating layer 111 and the third insulating layer 113. For example, when the circuit board of the embodiment includes four or more insulating layers, the second insulating layer 112 may include a plurality of insulating layers.

Each of the first insulating layer 111, the second insulating layer 112, and the third insulating layer 113 may have a thickness in a range of 10 um to 50 um. For example, each of the first insulating layer 111, the second insulating layer 112, and the third insulating layer 113 may have a thickness in a range of 15 um to 45 um. For example, each of the first insulating layer 111, the second insulating layer 112, and the third insulating layer 113 may have a thickness in a range of 20 um to 40 um.

At this time, the thickness of each of the first insulating layer 111, the second insulating layer 112, and the third insulating layer 113 may correspond to a distance in a thickness direction between circuit pattern layers disposed in different layers.

For example, the thickness of the first insulating layer 111 may mean a vertical distance between a lower surface of a first circuit pattern layer 121 and an upper surface of a second circuit pattern layer 122. For example, the thickness of the second insulating layer 112 may mean a vertical distance between a lower surface of a second circuit pattern layer 122 and the third circuit pattern layer 123. For example, the thickness of the third insulating layer 113 may mean a vertical distance between a lower surface of the third circuit pattern layer 123 and the fourth circuit pattern layer 124.

The upper surface of the first insulating layer 111 may be divided into a plurality of regions. For example, the first insulating layer 111 may include a first region R1 and a second region R2. The first region R1 may be a chip mounting region where a chip is disposed. The second region R2 may be a region excluding the first region R1.

A circuit pattern layer is disposed on the surface of the above insulating layer 110.

For example, a first circuit pattern layer 121 is disposed on an upper surface of the first insulating layer 111. For example, a second circuit pattern layer 122 is disposed on a lower surface of the first insulating layer 111 or an upper surface of the second insulating layer 112. For example, a third circuit pattern layer 123 is disposed on a lower surface of the second insulating layer 112 or an upper surface of the third insulating layer 113. For example, a fourth circuit pattern layer 124 is disposed on a lower surface of the third insulating layer 113.

In an embodiment, the circuit board can be manufactured using an ETS (Embedded Trace Substrate) method. Accordingly, at least one of the plurality of circuit patterns included in the circuit board can have an ETS structure. For example, an outermost circuit pattern layer of any one of the circuit patterns disposed on an outermost layer of the circuit board may be embedded in an insulating layer.

For example, the first circuit pattern layer 121 disposed on the upper surface of the first insulating layer 111 may have an ETS structure. For example, the first circuit pattern layer 121 may be a circuit pattern layer disposed at a first outermost side of the circuit board. Accordingly, the upper surface of the first circuit pattern layer 121 may be exposed to a first outermost side of the circuit board. A side surface and a lower surface of the first circuit pattern layer 121 may be covered with the first insulating layer 111.

For example, the upper surface of the first insulating layer 111 may have a recess concave from the upper surface of the first insulating layer 111 toward the lower surface of the first insulating layer 111. In addition, the first circuit pattern layer 121 may be disposed in the recess formed in the upper surface of the first insulating layer 111. Hereinafter, the recess provided in the upper surface of the first insulating layer 111 will be described as a ‘pattern groove’ to distinguish it from a recess provided in an upper surface of the first circuit pattern layer 121.

Meanwhile, in the embodiment, an upper surface of the first circuit pattern layer 121 may be positioned lower than an upper surface of the first insulating layer 111.

In other words, a depth of the pattern groove of the first insulating layer 111 may be greater than a thickness of the first circuit pattern layer 121. Therefore, the upper surface of the first circuit pattern layer 121 may be positioned lower than the upper surface of the first insulating layer 111. For example, the upper surface of the first circuit pattern layer 121 may include a recess concave toward the lower surface of the first circuit pattern layer 121. The recess may be formed by etching the upper surface of the first circuit pattern layer 121.

For example, the upper surface of the first circuit pattern layer 121 before the etching may have a same height as the upper surface of the first insulating layer 111. For example, a depth of the pattern groove of the first insulating layer 111 before the etching may be the same as a thickness of the first circuit pattern layer 121.

In addition, the upper surface of the first circuit pattern layer 121 after the etching may be positioned lower than the upper surface of the first insulating layer 111. For example, a depth of the pattern groove of the first insulating layer 111 after the etching may be greater than a thickness of the first circuit pattern layer 121.

Meanwhile, the first circuit pattern layer 121 may include a plurality of first pattern parts 121b and second pattern parts 121a depending on a location. In addition, an upper surface of the second pattern part 121a may be positioned higher than an upper surface of at least one pattern of the first pattern part 121b. At this time, the first pattern part 121b may be referred to as a “first circuit pattern part”, and the second pattern part 121a may be referred to as a “second circuit pattern part”.

In summary, the upper surface of the first insulating layer 111 is positioned higher than the upper surface of the first circuit pattern layer 121. In addition, an upper surface of at least one pattern part of the first circuit pattern layer 121 may have a different height from an upper surface of at least one other pattern part. This will be described in more detail below.

In addition, the second circuit pattern layer 122 may protrude downward from the lower surface of the first insulating layer 111. For example, the second circuit pattern layer 122 may have a structure embedded in the upper surface of the second insulating layer 112. A side surface and a lower surface of the second circuit pattern layer 122 may be covered with the second insulating layer 112.

In addition, the third circuit pattern layer 123 may protrude downward from the lower surface of the second insulating layer 112. For example, the third circuit pattern layer 123 may have a structure embedded in the upper surface of the third insulating layer 113. A side surface and a lower surface of the third circuit pattern layer 123 may be covered with the third insulating layer 113.

For example, the fourth circuit pattern layer 124 may have a structure that protrudes downward from the lower surface of the third insulating layer 113. For example, the fourth circuit pattern layer 124 may be a circuit pattern layer disposed at a second outermost side of the circuit board. Accordingly, side and lower surface of the fourth circuit pattern layer 124 may be exposed to a second outermost side of the circuit board.

Meanwhile, the circuit patterns of the embodiment may include traces and pads. For example, the first circuit pattern layer 121 and the fourth circuit pattern layer 124 disposed at the first and second outermost sides of the circuit board may include a mounting pad on which a chip is mounted or a terminal pad connected to an external substrate. In addition, the first circuit pattern layer 121 and the fourth circuit pattern layer 124 may include traces of long wires connected to the mounting pad or terminal pad.

The circuit pattern layers may be formed of at least one metal material selected from gold (Au), silver (Ag), platinum (Pt), titanium (Ti), tin (Sn), copper (Cu), and zinc (Zn). In addition, the circuit pattern layers may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the circuit pattern layers may be formed of copper (Cu) which has high electrical conductivity and is relatively inexpensive.

Each of the first circuit pattern layer 121, the second circuit pattern layer 122, the third circuit pattern layer 123, and the fourth circuit pattern layer 124 may have a thickness in a range of 5 μm to 40 μm. For example, each of the first circuit pattern layer 121, the second circuit pattern layer 122, the third circuit pattern layer 123, and the fourth circuit pattern layer 124 may have a thickness in a range of 6 μm to 35 μm. Each of the first circuit pattern layer 121, the second circuit pattern layer 122, the third circuit pattern layer 123, and the fourth circuit pattern layer 124 may have a thickness in a range of 7 μm to 32 μm. If the thickness of each of the first circuit pattern layer 121, the second circuit pattern layer 122, the third circuit pattern layer 123, and the fourth circuit pattern layer 124 is less than 5 um, resistance may increase and signal transmission efficiency may decrease. For example, if the thickness of each of the first circuit pattern layer 121, the second circuit pattern layer 122, the third circuit pattern layer 123, and the fourth circuit pattern layer 124 is less than 5 um, signal transmission loss may increase. For example, if the thickness of each of the first circuit pattern layer 121, the second circuit pattern layer 122, the third circuit pattern layer 123, and the fourth circuit pattern layer 124 exceeds 40 um, a line width of the circuit patterns may increase, and thus the overall volume of the circuit board may increase.

The first circuit pattern layer 121 may be smaller than the thickness of each of the second circuit pattern layer 122, the third circuit pattern layer 123, and the fourth circuit pattern layer 124. For example, the first circuit pattern layer 121 has a recess formed at the upper surface of the first circuit pattern layer 121. In addition, the first circuit pattern layer 121 may have a thickness smaller than a thickness of each of the second circuit pattern layer 122, the third circuit pattern layer 123, and the fourth circuit pattern layer 124 by a depth of the recess.

Meanwhile, the first circuit pattern layer 121 of the embodiment may include a fine pattern. In addition, correspondingly, the second circuit pattern layer 122, the third circuit pattern layer 123, and the fourth circuit pattern layer 124 may also include a fine pattern.

However, the circuit board in the embodiment includes a mounting region on which a chip of a semiconductor package is mounted on an upper portion of the first insulating layer 111. In addition, the first circuit pattern layer 121 includes a first pad connected to at least one chip and a trace connected to the first pad.

In addition, the embodiment miniaturizes the first circuit pattern layer 121 so that both the first pad and the trace connected to the chip can be disposed within a limited space. However, the embodiment is not limited thereto. For example, the fine patterns of the first circuit pattern layer 121 may be applied to at least one of the second circuit pattern layer 122, the third circuit pattern layer 123, and the fourth circuit pattern layer 124. Hereinafter, the first circuit pattern layer 121 will be described as a reference.

The first circuit pattern layer 121 may include a plurality of pattern parts.

For example, the first circuit pattern layer 121 may include a first pattern part 121b disposed in the first region R1. For example, the first circuit pattern layer 121 may include a second pattern part 121a disposed in the second region R2.

The first pattern part 121b is disposed in a chip mounting region where a chip (or semiconductor device) of a semiconductor package is disposed on the upper surface of the first insulating layer 111. For example, the first pattern part 121b may include a first-first pattern and a first-second pattern. At this time, the first-first pattern may be referred to as a ‘first electrode’, and the first-second pattern may be referred to as a ‘second electrode’.

The first-first pattern may mean a plurality of first pads 121b1 connected to a processor chip. In addition, the first-second pattern may include a trace 121b2 connected to the first pad 121b1. The first pattern part 121b may be a fine pattern.

The first pad 121b1 may have a first width W1. For example, when a planar shape of the first pad 121b1 is circular, the first width W1 may mean a diameter of the first pad 121b1. In addition, when a planar shape of the first pad 121b1 is oval, the first width W1 may mean a diameter of the first pad 121b1 in a short axis direction.

The first width W1 of the first pad 121b1 may have a range of 2 um to 20 um. Preferably, the first width W1 of the first pad 121b1 may have a range of 3 um to 18 um. More preferably, the first width W1 of the first pad 121b1 may have a range of 3.5 um to 17.5 um. If the first width W1 of the first pad 121b1 is less than 2 um, the electrical connectivity with the chip mounted on the circuit board may be deteriorated. If the first width W1 of the first pad 121b1 is less than 2 um, an allowable current of the signal transmitted through the first pad may be reduced. In addition, when the allowable current is reduced, the signal transmission characteristics may be deteriorated. If the first width W1 of the first pad 121b1 exceeds 20 um, it may be difficult to place all the first pads connected to the chip within a limited space. If the first width W1 of the first pad 121b1 exceeds 20 um, a volume of the circuit board and a volume of the semiconductor package may increase.

Meanwhile, the first pad 121b1 may have a normal size depending on an application product group. For example, the width of the first pad 121b1 may have a range of 15 um to 70 um. For example, the width of the first pad 121b1 may have a range of 18 um to 65 um. For example, the width of the first pad 121b1 may have a range of 20 um to 60 um.

A line width W2 of the trace 121b2 may be 12 um or less. For example, a line width W2 of the trace 121b2 may be 10 um or less. For example, a line width W2 of the trace 121b2 may be 8 um or less. For example, a line width W2 of the trace 121b2 may be 6 um or less.

For example, a line width W2 of the trace 121b2 may have a range of 1 um to 12 um. Preferably, a line width W2 of the trace 121b2 may have a range of 1.2 μm to 11.5 μm. More preferably, a line width W2 of the trace 121b2 may have a range of 1.5 μm to 10 μm.

If the line width W2 of the trace 121b2 is less than 1 μm, the signal resistance of the trace 121b2 increases, and thus, normal communication with the chip disposed on the circuit board may be difficult. In addition, if the line width W2 of the trace 121b2 is less than 1 μm, it is difficult to implement the trace, and a reliability problem may occur in which the trace 121b2 easily collapses during a process of manufacturing. In addition, if the line width W2 of the trace 121b2 exceeds 12 μm, it may be difficult to place all of the traces 121b2 connected to the first pad 121b1 within a limited space. If the line width W2 of the trace 121b2 exceeds 12 μm, the volume of the circuit board and the semiconductor package may increase.

A spacing W3 of the first pattern part 121b may have a range of 1 μm to 10 μm. For example, a spacing W3 of the first pattern part 121b may have a range of 1.2 μm to 9.5 μm. For example, a spacing W3 of the first pattern part 121b may have a range of 1.5 μm to 9 μm. In this case, the spacing W3 may mean a distance between adjacent first pattern parts 121b. For example, the spacing W3 may mean a spacing distance between neighboring plurality of traces 121b2. For example, the spacing W3 may mean a spacing distance between neighboring first pads 121b1. For example, the spacing W3 may mean a spacing distance between neighboring first pads and traces.

If the spacing W3 is less than 1 μm, an electrical short may occur due to neighboring pattern parts being connected to each other. If the spacing W3 is less than 1 μm, interference may occur between signals transmitted to neighboring pattern parts. In addition, if the spacing W3 exceeds 10 μm, it may be difficult to arrange all the first pads 121b1 and traces 121b2 within a limited space. If the spacing W3 exceeds 10 μm, the volume of the circuit board and the semiconductor package may increase.

The second pattern part 121a may have a width and spacing corresponding to the first pattern part 121b. However, the second pattern part 121a does not require miniaturization compared to the first pattern part 121b. Accordingly, the second pattern part 121a may have a width and spacing larger than that of the first pattern part 121b. The second pattern part 121a may mean a second pad connected to an external substrate (e.g., an interposer or a memory substrate). At this time, the second pad of the second pattern part 121a may be referred to as a ‘third electrode’.

The first pattern part 121b is divided into a first pad 121b1 and a trace 121b2 according to function as described above. At this time, an upper surface of the first pad 121b1 and an upper surface the trace 121b2 may have different heights.

Preferably, the upper surface of the first pad 121b1 and the upper surface of the trace 121b2 may be positioned lower than the upper surface of the first insulating layer 111.

Furthermore, the upper surface of the first pad 121b1 may be positioned lower than the upper surface of the trace 121b2.

That is, the upper surface of the first pad 121b1 may be positioned further away from the upper surface of the first insulating layer 111 than the upper surface of the trace 121b2.

That is, the thickness of the first pad 121b1 may be different from the thickness of the trace 121b2. For example, the thickness of the first pad 121b1 may be smaller than the thickness of the trace 121b2.

That is, a first recess 121b1R may be formed on the upper surface of the first pad 121b1. The first recess 121b1R may mean a concave portion that is concave toward the lower surface of the first pad 121b1 on the upper surface of the first pad 121b1. At this time, the upper surface of the first pad 121b1 including the first recess 121b1R may be flat. Unlike this, the upper surface of the first pad 121b1 including the first recess 121b1R may have a convex shape that is convex in an upward direction or a concave shape that is concave in a downward direction. At this time, a height of the upper surface of the first pad 121b1 may mean a height of a highest portion of the upper surface of the first pad 121b1, but is not limited thereto. A height of the upper surface of the first pad 121b1 may mean an average height of the entire height of the upper surface of the first pad 121b1, or, differently, may mean a height of a lowest portion of the upper surface of the first pad 121b1. However, standards for the height of the second pad and the height of the upper surface of the trace 121b2 described below may be the same as a standard for a height of the upper surface of the first pad 121b1. For example, if the height of the upper surface of the first pad 121b1 means the height of the highest portion of the upper surface of the first pad 121b1, the height of the upper surface of the second pad and the height of the upper surface of the trace 121b2 may also mean a height of a highest portion of a corresponding pattern.

At this time, the trace 121b2 of the first pattern part 121b does not overlap with the first protective layer 141 in the vertical direction. In other words, the trace 121b2 of the first pattern part 121b does not contact the first protective layer 141. Accordingly, the trace 121b2 may be damaged during the manufacturing process of the semiconductor package, etc. At this time, the embodiment allows the upper surface of the trace 121b2 to be positioned lower than the upper surface of the first insulating layer 111. In other words, the upper surface of the trace 121b2 includes a second recess 121b2R that is concave toward the lower surface of the trace 121b2. Accordingly, the embodiment can protect the trace 121b2 more stably, thereby improving reliability.

In addition, the upper surface of the first pad 121b1 is positioned lower than the upper surface of the trace 121b2. This means that a depth of the first recess 121b1R of the first pad 121b1 is greater than a depth of the second recess 121b2R of the trace 121b2.

For example, a recess is formed on each of the upper surfaces of the first pad 121b1 and the trace 121b2 through an etching process. At this time, a number of etching processes performed at the upper surface of the first pad 121b1 may be greater than a number of etching processes performed at the upper surface of the trace 121b2. Accordingly, the first pad 121b1 may be etched more than the trace 121b2. Accordingly, the height of the upper surface of the first pad 121b1 is positioned lower than the height of the upper surface of the trace 121b2. In addition, the depth of the first recess 121b1R formed on the upper surface of the first pad 121b1 may be greater than the depth of the second recess 121b2R formed on the upper surface of the trace 121b2.

That is, the first recess 121b1R may have a first depth H2. The first depth H2 of the first recess 121b1R may mean a vertical distance from the upper surface of the first insulating layer 111 to the upper surface of the first pad 121b1.

In addition, the second recess 121b2R may have a second depth H1 different from the first depth H2. The second depth H1 of the second recess 121b2R may mean a vertical distance from the upper surface of the first insulating layer 111 to the upper surface of the trace 121b2.

In addition, the second depth H1 is smaller than the first depth H2.

The second depth H1 may satisfy a range of 2 μm to 5 μm. For example, the second depth H1 may satisfy a range of 2.2 μm to 4.5 μm. For example, the second depth H1 may satisfy a range of 2.5 μm to 4 μm.

If the second depth H1 is less than 2 μm, the trace 121b2 may not be reliably protected in the manufacturing process of the circuit board or the usage environment of the circuit board or semiconductor package. For example, if the second depth H1 is less than 2 μm, damage may be applied to the trace 121b2 in the manufacturing process or the usage environment, and as a result, a problem may occur in which the trace 121b2 is peeled off from the first insulating layer 111. In addition, if the second depth H1 is greater than 5 μm, the physical reliability or electrical reliability of the trace 121b2 may be deteriorated. That is, the trace 121b2 has a relatively small line width. Accordingly, if the second depth H1 is greater than 5 um, a problem may occur in which not only the thickness of the trace 121b2 but also the line width of the trace 121b2 becomes smaller. For example, in a process of forming the second recess 121b2R, the second recess 121b1R may be formed not only in a vertical direction of the trace 121b2 but also in a horizontal direction. As a result, the trace 121b2 may not perform a normal signal transmission function. For example, if the second depth H1 is greater than 5 um, a circuit open problem in which the signal transmission line of the trace 121b2 is disconnected may occur.

Meanwhile, the first depth H2 is greater than the second depth H1. The first depth H2 may have a range of 5 μm to 18 μm. The first depth H2 may have a range of 6 μm to 16 μm. The first depth H2 may have a range of 7 μm to 15 μm. At this time, the first depth H2 may be determined by the thickness of the first circuit pattern layer 121 before etching. Here, the thickness of the first circuit pattern layer 121 before etching may mean a vertical distance from the upper surface of the first insulating layer 111 to the lower surface of the first circuit pattern layer 121. In addition, the first depth H2 may have a range of 10% to 70% of the thickness of the first circuit pattern layer 121 before etching. For example, the first depth H2 may have a range of 12% to 68% of the thickness of the first circuit pattern layer 121 before the etching. For example, the first depth H2 may have a range of 15% to 65% of the thickness of the first circuit pattern layer 121 before the etching.

If the first depth H2 is less than 5 μm, an effect derived by the embodiment may be insignificant. For example, if the first depth H2 is less than 5 μm, a connecting part may be diffused into the trace 121b2 adjacent to the first pad 121b1 during the chip mounting process. As a result, a circuit short problem may occur.

In addition, if the first depth H2 is greater than 18 μm, a process time for forming the first recess 121b1R corresponding to the first depth H2 may increase, and thus the product yield may decrease. In addition, if the first depth H2 is greater than 18 μm, the first pad 121b1 may not function normally as a mounting pad in the chip mounting process. For example, if the first depth H2 is greater than 18 μm, the thickness of the first pad 121b1 may become too thin, thereby deteriorating the electrical connectivity with the chip. In addition, if the first depth H2 is greater than 18 um, the thickness of the first pad 121b1 increases before the first recess 121b1R is formed, and the increase in the thickness may make it difficult to miniaturize the first pad 121b1 or trace 121b2 constituting the first pattern part 121b. In addition, if the miniaturization is difficult, the circuit integration may decrease, and the overall volume of the circuit board may increase accordingly. Furthermore, the process time and plating cost for forming the first circuit pattern layer 121 may increase due to the increase in the thickness.

Therefore, the upper surface of the first pad 121b1 has a step difference with the upper surface of the trace 121b2.

Meanwhile, the upper surface of the second pattern part 121a may have a height different from the height of the upper surface of at least one pattern of the first pattern part 121b.

For example, the upper surface of the second pattern part 121a may have a height different from the upper surface of the first pad 121b1 of the first pattern part 121b. Preferably, the upper surface of the second pattern part 121a may be positioned higher than the upper surface of the first pad 121b1 of the first pattern part 121b.

That is, the upper surface of the second pattern part 121a may be positioned between the upper surface of the first insulating layer 111 and the upper surface of the first pad 121b1. For example, the second pattern part 121a may include a second pattern. The second pattern may mean a second pad of the second pattern part 121a. The second pad may be a pad used to couple an additional external substrate on the circuit board of the embodiment in a POP (Package On Package) structure. The external substrate may be a memory substrate, but is not limited thereto.

In addition, the upper surface of the second pad of the second pattern part 121a is positioned higher than the upper surface of the first pad 121b1 of the first pattern part 121b. Furthermore, the upper surface of the second pad of the second pattern part 121a is positioned lower than the upper surface of the first insulating layer 111.

That is, a third recess 121aR that is concave toward the lower surface of the second pad of the second pattern part 121a may be formed on the upper surface of the second pad. In addition, a depth of the third recess 121aR may be smaller than the depth of the first recess 121b1R.

Accordingly, the thickness of the second pad of the second pattern part 121a may be greater than a thickness of the first pad 121b1 of the first pattern part 121b.

In addition, a height of the upper surface of the second pad of the second pattern part 121a may correspond to a height of the upper surface of the trace 121b2 of the first pattern part 121b. For example, the height of the upper surface of the second pad of the second pattern part 121a may be the same as the height of the upper surface of the trace 121b2 of the first pattern part 121b. For example, a depth of the third recess 121aR may be the same as a second depth H1 of the second recess 121b2R. However, the embodiment is not limited thereto. For example, depending on a process deviation in a manufacturing process, the height of the upper surface of the second pad of the second pattern part 121a may be different from the height of the upper surface of the trace 121b2 of the first pattern part 121b. However, a first difference between the height of the second pad of the second pattern part 121a and the height of the trace 121b2 of the first pattern part 121b may be smaller than a second difference between the height of the second pad of the second pattern part 121a and the height of the first pad 121b1 of the first pattern part 121b. Preferably, the first difference may be 50% or less, 40% or less, 30% or less, 20% or less, or 10% or less of the second difference. In this case, the first difference and the second difference may also be expressed as a distance in the vertical direction. For example, the first difference between the height of the second pad and the height of the trace 121b2 of the first pattern part 121b may mean a vertical distance from the upper surface of the second pad of the second pattern part 121a to the upper surface of the trace 121b2 of the first pattern part 121b. In addition, the second difference between the height of the second pad of the second pattern part 121a and the height of the first pad 121b1 of the first pattern part 121b may mean a vertical distance from the upper surface of the second pad of the second pattern part 121a to the upper surface of the first pad 121b1 of the first pattern part 121b.

That is, the circuit board of the first embodiment allows the thickness or height of the pattern part of the first circuit pattern layer 121 directly connected to the chip through the first connecting part to be smaller than the thickness or height of other pattern parts of the first circuit pattern layer 121. Through this, the embodiment can prevent overflow of the first connecting part, and further improve the electrical reliability of the circuit board.

Meanwhile, the circuit board of the embodiment includes a through electrode.

The through electrode penetrates the insulating layer 110 included in the circuit board of the embodiment, and thus can electrically connect circuit patterns disposed in different layers. At this time, the through electrode may be formed by penetrating only one insulating layer, or alternatively, may be formed by penetrating at least two or more insulating layers in common.

For example, the circuit board includes a first through electrode 131. The first through electrode 131 penetrates the first insulating layer 111. The first through electrode 131 can electrically connect between the first circuit pattern layer 121 and the second circuit pattern layer 122. For example, an upper surface of the first through electrode 131 may be directly connected to the lower surface of the first circuit pattern layer 121. For example, a lower surface of the first through electrode 131 may be directly connected to the upper surface of the second circuit pattern layer 122. In addition, the first circuit pattern layer 121 and the second circuit pattern layer 122 may be electrically connected to each other through the first through electrode 131 to transmit a signal.

For example, the circuit board includes the second through electrode 132. The second through electrode 132 may penetrate the second insulating layer 112. The second through electrode 132 may electrically connect the second circuit pattern layer 122 and the third circuit pattern layer 123. For example, the upper surface of the second through electrode 132 may be directly connected to the lower surface of the second circuit pattern layer 122. For example, the lower surface of the second through electrode 132 may be directly connected to the upper surface of the third circuit pattern layer 123. Accordingly, the second circuit pattern layer 122 and the third circuit pattern layer 123 can be directly electrically connected to each other through the second through electrode 132 to transmit a signal.

For example, the circuit board includes a third through electrode 133.

The third through electrode 133 can be formed by penetrating the third insulating layer 113. The third through electrode 133 can electrically connect the third circuit pattern layer 123 and the fourth circuit pattern layer 124. For example, the upper surface of the third through electrode 133 can be directly connected to the lower surface of the third circuit pattern layer 123. For example, the lower surface of the third through electrode 133 can be directly connected to the upper surface of the fourth circuit pattern layer 124. Accordingly, the third circuit pattern layer 123 and the fourth circuit pattern layer 124 can be electrically connected to each other to transmit signals.

The first through electrode 131, the second through electrode 132, and the third through electrode 133 as described above can be formed by filling a through hole penetrating the insulating layer 110 with a conductive material.

The through hole can be formed by any one of mechanical, laser, and chemical processing methods. For example, the through-hole can be formed using any one of milling, drilling, routing, UV laser, CO2 laser, amino silane agent, and ketone agent.

The metal material forming the through electrode can be any one material selected from copper (Cu), silver (Ag), tin (Sn), gold (Au), nickel (Ni), and palladium (Pd). In addition, the conductive material filling of the through hole can be performed using any one of electroless plating, electrolytic plating, screen printing, sputtering, evaporation, ink jetting, and dispensing.

Meanwhile, the circuit board of the embodiment includes a protective layer.

The protective layer includes a first protective layer 141 disposed on the upper surface of the first insulating layer 111. In addition, the protective layer includes a second protective layer 142 disposed on the lower surface of the third insulating layer 113. The first protective layer 141 and the second protective layer 142 may be solder resists, but are not limited thereto.

The first protective layer 141 may be selectively disposed on the second region R2 of the first insulating layer 111 excluding the first region R1 of the first insulating layer 111. That is, the first protective layer 141 is not disposed in the first region R1 of the first insulating layer 111. Accordingly, the first pattern part 121b of the first circuit pattern layer 121 disposed in the first region R1 does not contact the first protective layer 141.

In other words, a fact that the first protective layer 141 is not disposed in the first region R1 may mean that the first protective layer 141 includes a first opening 141-2 that entirely opens the first region R1.

The first protective layer 141 is selectively disposed in the second region R2 of the first insulating layer 111.

The first protective layer 141 may include a second opening 141-1 that partially opens the second region R2.

For example, the second region R2 may include a second-first region R21 overlapping the first protective layer 141 in a vertical direction and a second-second region R22 overlapping the second opening 141-1 of the first protective layer 141 in the vertical direction.

In addition, the second-second region R22 may vertically overlap the upper surface of the second pad of the second pattern part 121a. For example, at least a portion of the upper surface of the second pad of the second pattern part 121a may vertically overlap the second opening 141-1 of the first protective layer 141. Therefore, at least a portion of the upper surface of the second pad of the second pattern part 121a may not be in contact with the first protective layer 141.

Meanwhile, a difference between the first opening 141-2 and the second opening 141-1 of the first protective layer 141 can be distinguished by size. A size of the first opening 141-2 can be larger than a size of the second opening 141-1. The size can mean an area.

Preferably, the first opening 141-2 can be vertically overlapped with a plurality of first pads 121b1 and a plurality of traces 121b2 constituting the first pattern part 121b of the first circuit pattern layer 121.

In addition, the second opening 141-1 can be partially overlapped with one second pad constituting the second pattern part 121a of the first circuit pattern layer 121 in the vertical direction.

Meanwhile, although not shown in the drawing, a surface treatment layer may be disposed on the first pad 121b1 and the second pad that are vertically overlapped with the first opening 141-2 and the second opening 141-1 of the first protective layer 141. The surface treatment layer may be an OSP (Organic Solderability Preservative) layer. For example, the surface treatment layer may be an organic coating layer coated with an organic material such as benzimidazole. However, the embodiment is not limited thereto. For example, the surface treatment layer may be a plating layer. For example, the surface treatment layer may include at least one of a nickel (Ni) plating layer, a palladium (Pd) plating layer, and a gold (Au) plating layer.

Referring to FIG. 6, the circuit pattern layer and the through electrode may have a multi-layer structure. However, in the embodiment, the first circuit pattern layer 121 among the circuit patterns has an ETS structure, and accordingly, the first circuit pattern layer 121 having the ETS structure may have a different layer structure from other circuit pattern layers and the through electrodes.

For example, the first circuit pattern layer 121 may have a different layer structure from the second circuit pattern layer 122, the third circuit pattern layer 123, and the fourth circuit pattern layer 124. For example, the first circuit pattern layer 121 may have a number of layers smaller than the number of layers of the second circuit pattern layer 122, the third circuit pattern layer 123, and the fourth circuit pattern layer 124.

For example, the first circuit pattern layer 121 may include only an electroplating layer.

Differently, the second circuit pattern layer 122, the third circuit pattern layer 123, and the fourth circuit pattern layer 124 may each include a seed layer and an electroplating layer.

For example, the first circuit pattern layer 121 may have a single-layer structure. For example, the seed layer of the first circuit pattern layer 121 may be finally removed during a process of manufacturing. Therefore, the first circuit pattern layer 121 may include only an electroplating layer.

For example, the second circuit pattern layer 122, the third circuit pattern layer 123, and the fourth circuit pattern layer 124 may each have a multi-layer structure. For example, the second circuit pattern layer 122 may include a seed layer 122-1 and an electroplating layer 122-2. For example, the third circuit pattern layer 123 may include a seed layer 123-1 and an electrolytic plating layer 123-2. For example, the fourth circuit pattern layer 124 may include a seed layer 124-1 and an electrolytic plating layer 124. In addition, correspondingly, the through electrode included in the circuit board may include a seed layer and an electrolytic plating layer. For example, the first through electrode 131 may include a seed layer 131-1 and an electrolytic plating layer 131-2. For example, the second through electrode 132 may include a seed layer 132-1 and an electrolytic plating layer 132-2. For example, the third through electrode 133 may include a seed layer 133-1 and an electrolytic plating layer 133-2.

Meanwhile, when the circuit board of the embodiment is manufactured by a MSAP method, at least one of the second circuit pattern layer, the third circuit pattern layer, and the fourth circuit pattern layer may further include a metal layer corresponding to a copper layer.

As described above, the upper surface of the first circuit pattern layer disposed at an uppermost side of the embodiment may have a step difference from the upper surface of the first insulating layer. Furthermore, an upper surface of at least one pattern part of the first circuit pattern layer may have a step difference from an upper surface of at least one other pattern part. Accordingly, the overall electrical reliability and physical reliability of the circuit board and the semiconductor package may be improved.

To summarize, the following is as follows.

The embodiment can improve electrical reliability and physical reliability of a circuit board and a semiconductor package including the same.

The circuit board of the embodiment includes a first insulating layer, a first circuit pattern layer, and a first protective layer. At this time, the first insulating layer means an outermost insulating layer among a plurality of insulating layers of the circuit board. The first circuit pattern layer means an outermost circuit pattern layer among a plurality of circuit pattern layers of the circuit board. At this time, the first circuit pattern layer has an ETS structure. For example, the first circuit pattern layer is embedded in an upper surface of the first insulating layer.

At this time, the upper surface of the first circuit pattern layer has a step difference with the upper surface of the first insulating layer. Specifically, the upper surface of the first circuit pattern layer is positioned lower than the upper surface of the first insulating layer. The first circuit pattern layer includes a fine pattern. The fine pattern may be damaged by various factors in a manufacturing process and an usage environment of the circuit board. At this time, the embodiment allows the upper surface of the first circuit pattern layer to be positioned lower than the upper surface of the first insulating layer. Accordingly, the embodiment can stably protect the first circuit pattern layer from the damage. Therefore, the embodiment can solve a peeling problem or collapse problem of the first circuit pattern layer. Through this, the embodiment can improve the physical reliability and electrical reliability of the circuit board and the semiconductor package.

Meanwhile, the first circuit pattern layer can be divided into a plurality of pattern parts according to a location. That is, the first circuit pattern layer includes a first pattern part disposed in a first region where a chip is mounted and a second pattern part disposed in a second region other than the first region. The first protective layer is not disposed on the first region. In other words, the first protective layer includes a first opening that vertically overlaps the first region as a whole.

At this time, the first pattern part includes a first pad and a trace that vertically overlap the first opening. In addition, the second pattern part includes a second pad that vertically overlaps the second opening. At this time, the upper surface of the first pad can have a step difference from the upper surface of the trace and the upper surface of the second pad. That is, the upper surface of the first pad may be positioned lower than the upper surface of the trace and the upper surface of the second pad. In other words, a first recess may be formed on the upper surface of the first pad, a second recess may be formed on the upper surface of the trace, and a third recess may be formed on the upper surface of the second pad. In addition, a depth of the first recess may be greater than each of depths of the second recess and the third recess.

At this time, the first pad is a mounting pad on which a chip is mounted, and a connecting part such as solder is disposed on the upper surface of the first pad. At this time, the first protective layer is not disposed on the first region where the first pad is disposed, and thus overflow of the connecting part may occur. Accordingly, the embodiment allows the upper surface of the first pad to be positioned lower than the trace and the upper surface of the second pad, thereby securing a space for arranging the connecting part without increasing the overall thickness of the circuit board.

Accordingly, the embodiment can prevent diffusion of the connecting part and solve the circuit short problem caused by diffusion of the connecting part.

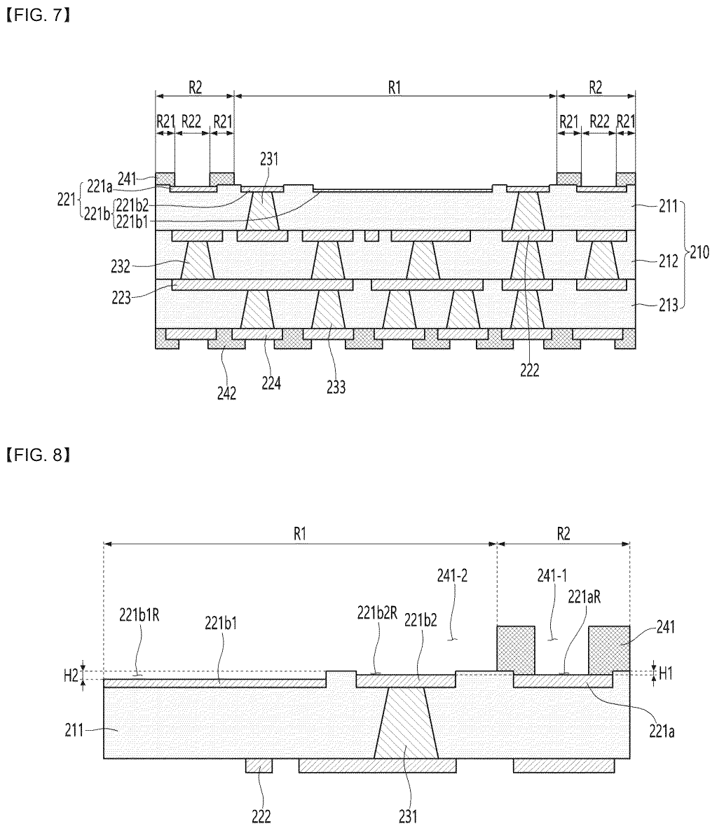

FIG. 7 is a drawing showing a circuit board according to a second embodiment, and FIG. 8 is an enlarged view of a partial region of FIG. 7.

Referring to FIGS. 7 and 8, the circuit board of a second embodiment can provide a mounting space that allows a chip to be mounted in a wire bonding manner.

For example, the circuit board of the first embodiment of FIG. 3 provides a mounting space that allows a chip to be mounted in a flip chip manner. Differently, the circuit board of the second embodiment allows a chip to be mounted in a wire bonding manner.

The circuit board of the second embodiment includes an insulating layer 210 that includes a first insulating layer 211, a second insulating layer 212, and a third insulating layer 213.

In addition, the circuit board of the second embodiment includes a first circuit pattern layer 221, a second circuit pattern layer 222, a third circuit pattern layer 223, and a fourth circuit pattern layer 224.

In addition, the first circuit pattern layer 221 includes a first pattern part 221b and a second pattern part 221a. In addition, the first pattern part 221b includes a first-first pattern and a first-second pattern. In addition, the second pattern part 221a includes a second pattern.

In addition, the circuit board of the second embodiment includes a first through electrode 231, a second through electrode 232, and a third through electrode 233.

In addition, the circuit board of the second embodiment includes a first protective layer 241 and a second protective layer 242.

The first protective layer 241 includes a first opening 241-2 that is vertically overlapped with the first region R1 as a whole. In addition, the first protective layer 141 includes a second opening 241-1 that is partially overlapped with the second region R2.

In addition, a first recess 221b1R is formed on the first-first pattern of the first pattern part 221b, and a second recess 221b2R is formed on the first-second pattern. In addition, a third recess 221aR is formed on a second pad corresponding to the second pattern of the second pattern part 221a.

At this time, in the circuit board of the second embodiment, the first pattern part 221b that constitutes the first circuit pattern layer is different from the circuit board of the first embodiment. Accordingly, only the first pattern part 221b constituting the first pattern part 221b of the second embodiment will be described below.

That is, a difference between the first embodiment and the second embodiment is functions of the first-first pattern and the first-second pattern constituting the first pattern part.

The first-first pattern of the first pattern part 121b of the first embodiment was the first pad 121b1 on which the chip is mounted, and the first-second pattern was the trace 121b2 connected to the first pad 121b1.

Differently, the first-first pattern of the first pattern part 221b of the second embodiment is the first pad 221b1 on which the chip is attached, and the first-second pattern means a bonding pattern 221b2 connected to the chip through a connecting member.

For example, the first-first pattern of the first pattern part 221b of the second embodiment means a first pad 221b1 of a dummy pad that provides a space to which the chip is attached. Therefore, the first pad 221b1 of the second embodiment is not electrically connected to the chip.

The first pad 221b1 may have a first recess 221b1R corresponding to the first pad 121b1 of the first embodiment. In addition, the bonding pattern 221b2 may have a second recess 221b2R corresponding to the trace 121b2 of the first embodiment.

At this time, the circuit board of the second embodiment includes the first pad 221b1 of the first-first pattern, which is a dummy pattern for providing a space to which the chip can be attached. In addition, the first pad 221b1 is positioned lower than the upper surface of the first insulating layer 211. For example, a first recess 221b1R having a step difference from the upper surface of the first insulating layer 211 is formed on the first pad 221b1. Then, a chip can be inserted into the first recess 221b1R of the first pad 221b1. That is, the first recess 221b1R of the first pad 221b1 of the second embodiment can function as a cavity in which a chip is disposed. Accordingly, in the second embodiment, in a structure in which a chip is disposed by a wire bonding method, the thickness of the semiconductor package can be reduced by a height corresponding to the depth H2 of the first recess 221b1R.

That is, the first circuit pattern layer in the embodiment includes a first pad, which is a dummy pattern, and a bonding pattern. Then, a chip can be attached on the first pad. Then, the bonding pattern can be connected to the chip through a connecting member such as a wire. At this time, a first recess is formed on the first pad, and a second recess is formed on the bonding pattern. In addition, a depth of the first recess may be greater than a depth of the second recess. The first recess may function as a cavity into which a chip is inserted.

Accordingly, the embodiment may lower the height at which the chip is disposed by the depth of the first recess. Therefore, the embodiment may reduce the overall thickness of the circuit board and the semiconductor package.

### —Semiconductor Package—

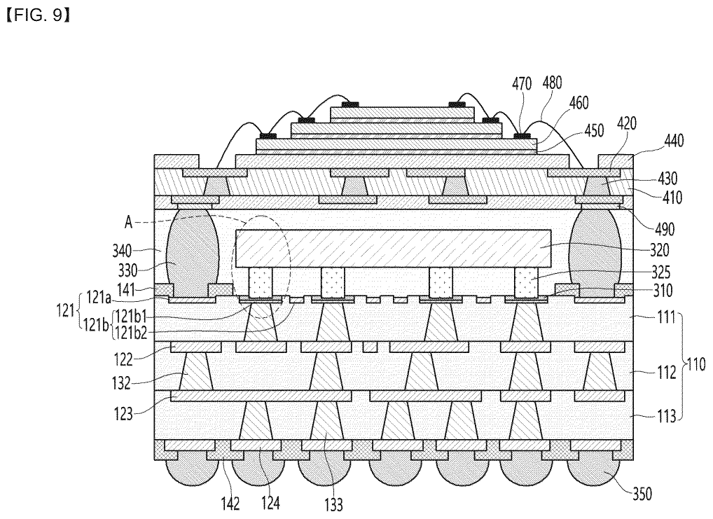

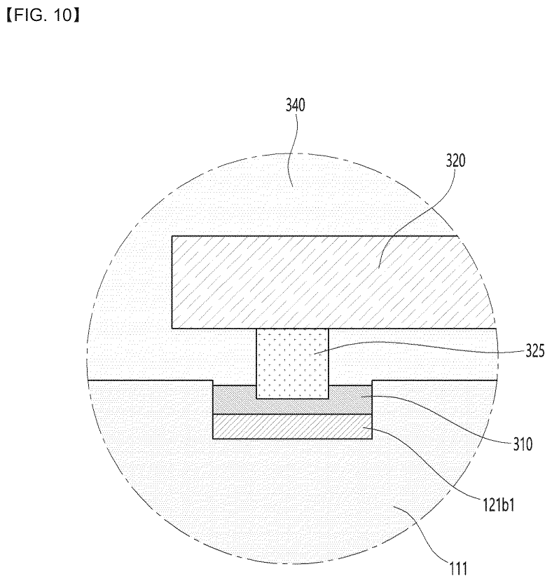

FIG. 9 is a drawing showing a semiconductor package according to a first embodiment, and FIG. 10 is an enlarged view of a chip arrangement region of FIG. 9.

Referring to FIGS. 9 and 10, a semiconductor package of a first embodiment includes the circuit board of the first embodiment of FIG. 3.

In addition, the semiconductor package includes a first connecting part 310.

The first connecting part 310 may be disposed in the first recess 121b1R of the first pad 121b1 of the first circuit pattern layer 121 of the circuit board. For example, the first connecting part 310 may be solder.

The first connecting part 310 may be disposed in the first recess 121b1R having the first depth H2 of the first embodiment and may be coupled to the first pad 121b1.

The first connecting part 310 may have a spherical shape. For example, a cross-section of the first connecting part 310 may have a circular shape or a semicircular shape. For example, a cross-section of the first connecting part 310 may have a partially or entirely rounded shape. For example, a cross-sectional shape of the first connecting part 310 may be flat at one side and curved at the other side.

Unlike this, the first connecting part 310 may have a hexahedral shape. The cross-section of the first connecting part 310 may include a square shape. The cross-section of the first connecting part 310 may include a rectangle or a square.

An upper surface of the first connecting part 310 may have a step. For example, the upper surface of the first connecting part 310 may include a first upper surface that vertically overlaps a terminal 325 of the chip 320 and a second upper surface excluding the first upper surface. In addition, the first upper surface of the first connecting part 310 may be positioned lower than the second upper surface.

The semiconductor package may include a chip 320 or a device 320 disposed on the first connecting part 310.

The chip 320 may be a processor chip. For example, the chip 320 may be an application processor (AP) chip of any one of a central processor (e.g., a CPU), a graphic processor (e.g., a GPU), a digital signal processor, an encryption processor, a microprocessor, and a microcontroller.

At this time, a terminal 325 may be provided at the lower surface of the chip 320, and the terminal 325 may be connected to the first pad 121b1 of the circuit board through the first connecting part 310. At this time, the terminal 325 of the chip 320 may be a pillar that extends downward from the lower surface of the chip 320.

Meanwhile, the semiconductor package of the first embodiment may include a plurality of chips that are disposed on one circuit board while being spaced apart from each other in the horizontal direction.

For example, the chip 320 may include a first chip and a second chip that are spaced apart from each other. In addition, the first chip and the second chip may be different types of application processor (AP) chips.

Meanwhile, the first chip and the second chip may be spaced apart by a certain distance on the circuit board. For example, a distance between the first chip and the second chip may be 150 μm or less. For example, a distance between the first chip and the second chip may be 120 μm or less. For example, a distance between the first chip and the second chip may be 100 μm or less.

Preferably, for example, the distance between the first chip and the second chip may have a range between 60 μm and 150 μm. For example, the distance between the first chip and the second chip may have a range between 70 μm and 120 μm. For example, the gap between the first chip and the second chip may have a range of 80 μm to 110 μm. For example, if the distance between the first chip and the second chip is smaller than 60 μm, a problem may occur in the operational reliability of the first chip or the second chip due to interference between the first chip and the second chip. For example, if the distance between the first chip and the second chip is larger than 150 μm, signal transmission loss may increase as the distance between the first chip and the second chip increases.

Meanwhile, at least a part of the terminal 325 of the chip 320 may be positioned lower than the upper surface of the first insulating layer 111 of the circuit board. For example, at least a part of the pillar constituting the terminal 325 of the chip 320 may be disposed within the first recess 121b1R of the first pad 121b1.

The semiconductor package may include a second connecting part 330.

The second connecting part 330 may be disposed on a second pad of a second pattern part 121a of the circuit board. For example, the second connecting part 330 may be disposed in a second opening 141-1 of a first protective layer 141 that vertically overlaps the second pad. The second connecting part 330 may be a bump. For example, the second connecting part 330 may be a solder bump, but is not limited thereto. For example, the second connecting part 330 may be a post bump.

For example, the second connecting part 330 may include a copper post and a solder bump disposed on the copper post. An upper surface of the second connecting part 330 may be positioned higher than an upper surface of the chip 320. Through this, it is possible to prevent the chip 320 from being damaged during a bonding process of the external substrate disposed on the second connecting part 330.

The semiconductor package may include a molding layer 340. The molding layer 340 may mold the chip 320. At this time, in the embodiment, the chip 320 is illustrated as being entirely molded by the molding layer 340, but it is not limited thereto.

For example, the molding layer 340 may include an underfill disposed around a region where the chip 320 is disposed. In addition, the chip 320 may be covered by the underfill.

At this time, the second recess 121b2R of the trace 121b2 of the first pattern part 221b that vertically overlaps the first opening 141-2 of the first protective layer 141 may be filled with the molding layer 340.

The molding layer 340 may be EMC (Epoxy Mold Compound), but is not limited thereto. The molding layer 340 may have a low dielectric constant. For example, a dielectric constant (Dk) of the molding layer 340 may be 0.2 to 10. For example, a dielectric constant (Dk) of the molding layer 340 may be 0.5 to 8. For example, a dielectric constant (Dk) of the molding layer 340 may be 0.8 to 5. Accordingly, in the embodiment, the molding layer 340 may have a low dielectric constant, thereby improving the heat dissipation characteristics of heat generated from the chip 320. The molding layer 340 may include an opening. For example, the molding layer 340 may include an opening that vertically overlaps the upper surface of the second connecting part 330.

The semiconductor package includes a third connecting part 350.

The third connecting part 350 may be disposed on the lower surface of the fourth circuit pattern layer 124. For example, the third connecting part 350 may be a solder for connecting the semiconductor package of the embodiment to a separate external substrate (e.g., a main board of an electronic device), but is not limited thereto.

The semiconductor package includes an external substrate. The external substrate may mean a separate substrate coupled with the circuit board of the embodiment.

That is, the chip 320 mounted on the circuit board may be a logic chip such as a processor chip of a CPU or GPU, and the external substrate may mean a memory substrate on which a memory chip connected to the logic chip is disposed. The external substrate may be a memory substrate on which a memory chip 460 corresponding to the memory chip is disposed. Alternatively, the external substrate may be an interposer connecting between the memory substrate and the circuit board.

The external substrate may include an insulating layer 410, a circuit layer 420, a through electrode 430, and a protective layer 440.

In addition, the external substrate may include an adhesive layer 450 disposed on the circuit layer 420, a memory chip 460 attached on the adhesive layer 450, and a connecting member 480 connecting between a terminal 470 of the memory chip 460 and the circuit layer 420.

In addition, the semiconductor package may include a fourth connecting part 490. The fourth connecting part 490 may be disposed between the external substrate and the second connecting part 330.

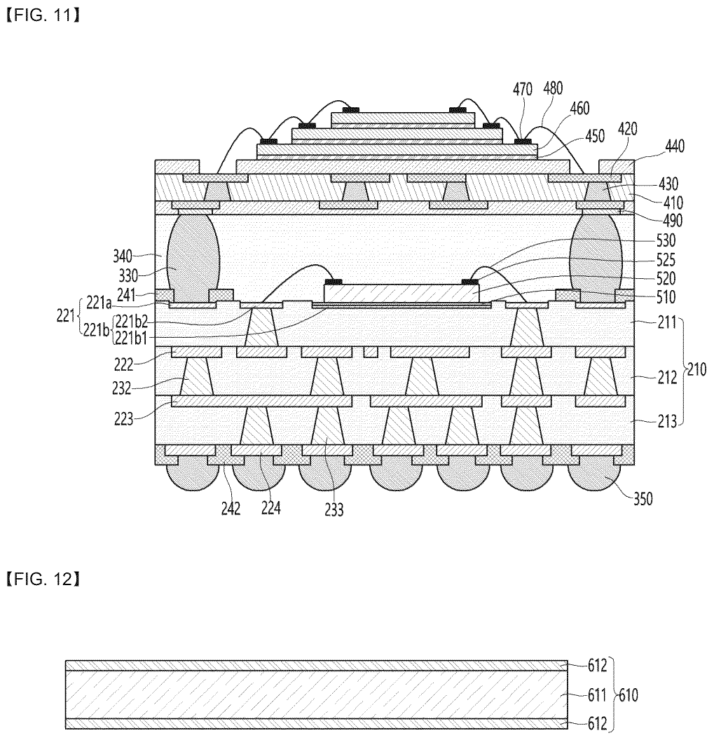

FIG. 11 is a drawing showing a semiconductor package according to the second embodiment.

Referring to FIG. 11, the semiconductor package of the second embodiment includes the circuit board of the second embodiment of FIG. 7.

At this time, the semiconductor package of the second embodiment has a difference in a method of mounting a chip on the circuit board compared to the semiconductor package of the first embodiment. Therefore, ae method of mounting the chip will be described below.

The circuit board of the second embodiment includes a first pad 221b1, which is a dummy pad including a first recess 221b1R.

In addition, the semiconductor package includes an adhesive member 510 disposed on the first pad 221b1.

In addition, the semiconductor package includes a chip 520 attached on the adhesive member 510. At this time, a terminal 525 of the chip 520 is disposed toward an upper side. In addition, at least a part of the chip 520 is disposed in the first recess 221b1R formed on the first pad 221b1. Therefore, the embodiment can reduce a thickness of the semiconductor package by the depth of the first recess 221b1R.

In addition, the semiconductor package can include a connecting member 530 connecting the bonding pattern 221b2 of the first pad 221b1 and the terminal 525 of the chip 520.

### —Manufacturing Method—

Hereinafter, a method for manufacturing a circuit board according to the embodiment will be described. Specifically, a method for manufacturing a circuit board illustrated in FIG. 3 will be described in order of processes below.

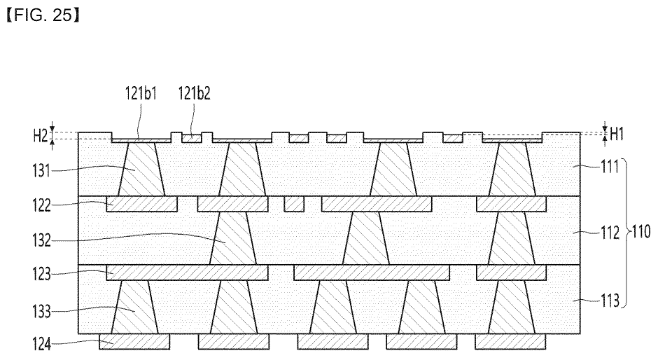

FIGS. 12 to 25 are cross-sectional views showing a manufacturing method of a circuit board illustrated in FIG. 3 in order of processes.

Referring to FIG. 12, the embodiment may prepare a base material for manufacturing a circuit board by an ETS method.

For example, the embodiment may prepare a carrier insulating layer 611 and a carrier board 610 in which a metal layer 612 is disposed on at least one surface of the carrier insulating layer 611. At this time, the metal layer 612 can be disposed on only one surface among a first surface and a second surface of the carrier insulating layer 611, or alternatively, the metal layer 612 can be disposed on both surfaces. For example, the metal layer 612 is disposed on only one surface of the carrier insulating layer 611, and accordingly, an ETS process for manufacturing a circuit board can be performed only on the one surface. Unlike this, the metal layer 612 can be disposed on both surfaces of the carrier insulating layer 611, and thus, the ETS process for manufacturing the circuit board can be performed simultaneously on both surfaces of the carrier board 610. In this case, two circuit boards can be manufactured at one time.

The metal layer 612 can be formed by electroless plating the carrier insulating layer 611. Unlike this, the carrier insulating layer 611 and the metal layer 612 can be CCL (Copper Clad Laminate). That is, the metal layer 612 can be a copper layer. For example, the metal layer 612 can be a copper foil. For example, the metal layer 612 can be an electroless plating layer formed on the carrier insulating layer 611. That is, the metal layer 612 is a metal layer formed first in a circuit board manufacturing process. In addition, the metal layer 612 can be used as a seed layer of the first circuit pattern layer 121 formed in a subsequent process.

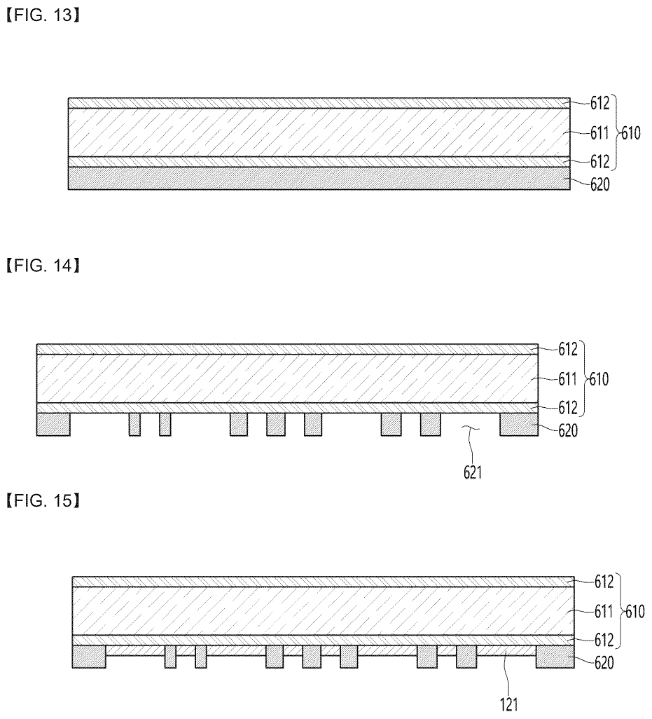

Next, referring to FIG. 13, in the embodiment, a first dry film 620 is formed on the metal layer 612. At this time, the first dry film 620 can be disposed to completely cover the metal layer 612.

Next, referring to FIG. 14, in the embodiment, the first dry film 620 can be exposed and developed.

Specifically, the embodiment may proceed with a process of forming an opening 621 that exposes the surface of the metal layer 612 by exposing and developing the first dry film 620.

An opening 621 can be formed on a surface of the metal layer 612 to correspond to a region where the first circuit pattern layer 121 is to be formed.

Next, referring to FIG. 15, the embodiment may perform a process of forming a first circuit pattern layer 121 that fills the opening 621 of the first dry film 620 by electrolytic plating the metal layer 612 as a seed layer.

At this time, the embodiment may additionally perform a curing process of heat-treating the first dry film 620 before the electrolytic plating process of the first circuit pattern layer 121. For example, the embodiment may perform a process of curing the first dry film 620 after the exposure and development process of the first dry film 620. The curing of the first dry film 620 may include curing using ultraviolet rays and curing using infrared rays. For example, the embodiment may cure the first dry film 620 using ultraviolet rays in a range of 5 mV to 100 mV. In contrast, the embodiment may perform infrared thermal curing of the first dry film 620. As described above, the embodiment may further perform a process of curing the first dry film 620, thereby improving the bonding strength between the metal layer 612 and the first dry film 620. Accordingly, the embodiment may further improve the bonding strength between the first dry film 620 and the metal layer 612, thereby miniaturizing the first circuit pattern layer 121 formed in the opening 621. For example, the embodiment may further perform a process of curing the first dry film 620, thereby reducing the line width and spacing of the trace 121b2 of the first circuit pattern layer 121.

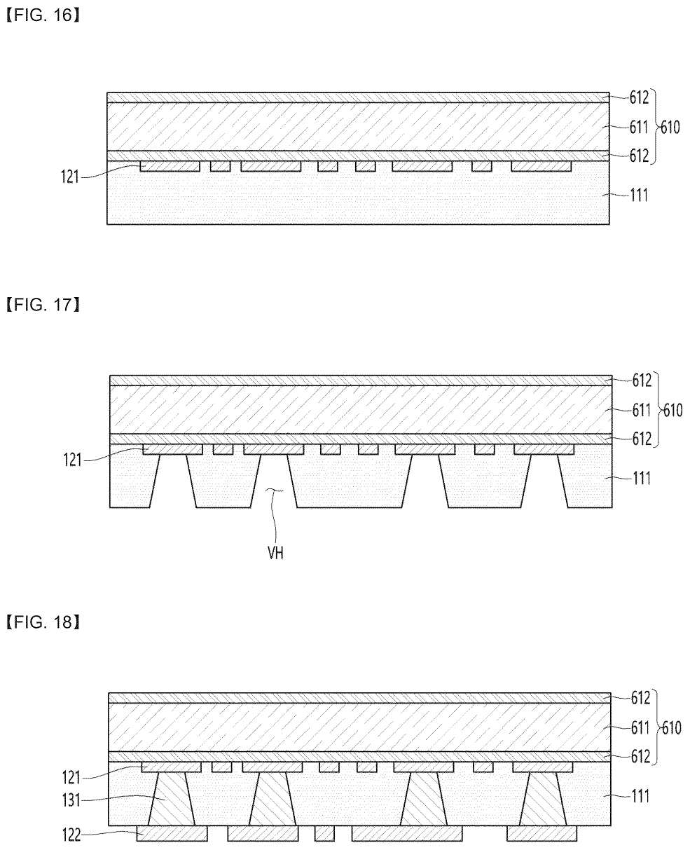

Next, referring to FIG. 16, the embodiment may perform a process of removing the first dry film 620 when the first circuit pattern layer 121 is formed. In addition, the embodiment can perform a process of preprocessing the first circuit pattern layer 121 as the first dry film 620 is removed. For example, the embodiment can perform a process of imparting a surface roughness of a certain level or higher to a surface of the first circuit pattern layer 121. For example, the embodiment can perform a surface treatment of the first circuit pattern layer 121 so that the surface of the first circuit pattern layer 121 has a 10-point average surface roughness (Rz) in a range of 0.01 um to 0.5 um.

Thereafter, the embodiment can form a first insulating layer 111 covering the first circuit pattern layer 121 on the metal layer 612.

Next, referring to FIG. 17, the embodiment can perform a process of forming a through hole (VH) in the first insulating layer 111. The through hole (VH) may be formed by laser processing, but is not limited thereto.

Next, referring to FIG. 18, the embodiment may perform a process of forming a first through electrode 131 and a second circuit pattern layer 122.

Specifically, the embodiment may perform a process of forming a seed layer on the lower surface of the first insulating layer 111 and an inner wall of the through hole (VH), and performing electrolytic plating using the seed layer to form the second circuit pattern layer 122 and the first through electrode 131.

Next, the embodiment may perform a lamination process by repeatedly performing the processes illustrated in FIGS. 16 to 18, as illustrated in FIG. 19.

Specifically, the embodiment may perform a process of forming a second insulating layer 112 covering the second circuit pattern layer 122 on the lower surface of the first insulating layer 111. Next, the embodiment can proceed with a process of forming a second through electrode 132 penetrating the second insulating layer 112 and a third circuit pattern layer 123 protruding from the lower surface of the second insulating layer 112.

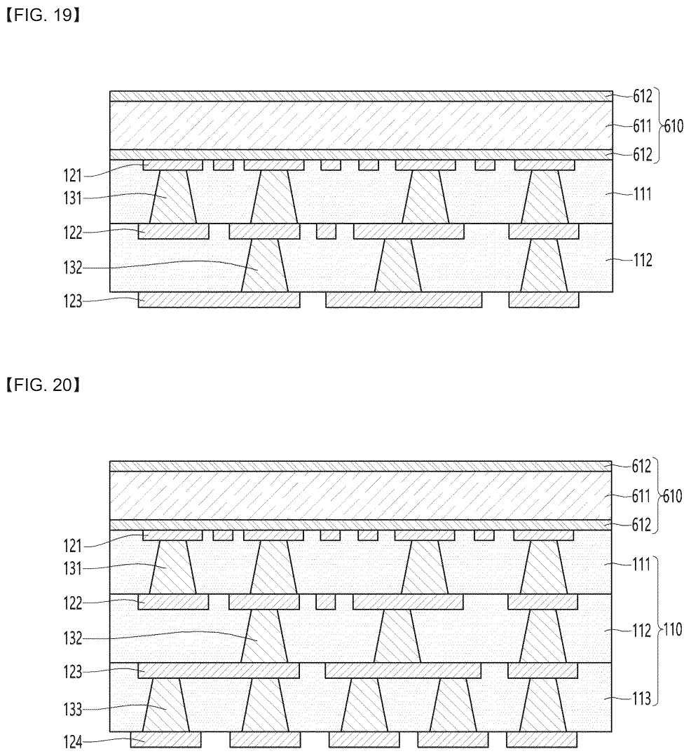

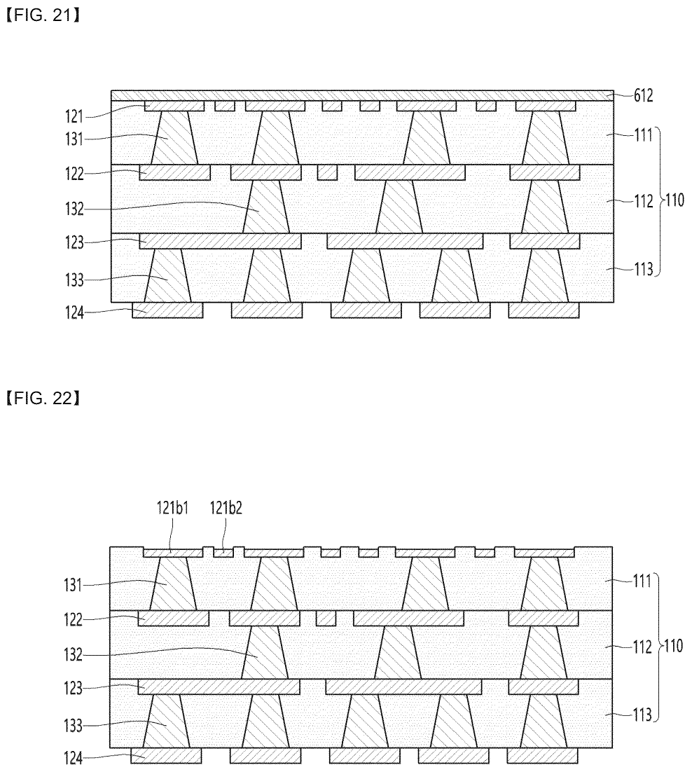

Next, the embodiment can proceed with an additional lamination process by repeatedly proceeding with a process illustrated in FIG. 19, as illustrated in FIG. 20.

Specifically, the embodiment can proceed with a process of forming a third insulating layer 113 covering the third circuit pattern layer 123 on the lower surface of the second insulating layer 112. Next, the embodiment can proceed with a process of forming a third through electrode 133 penetrating the third insulating layer 113 and a fourth circuit pattern layer 124 protruding from the lower surface of the third insulating layer 113.

Next, referring to FIG. 21, the embodiment can proceed with a process of removing a carrier board from the circuit board manufactured as described above. For example, the embodiment may perform a process of separating the carrier insulating layer 611 and the metal layer 612 from each other in the carrier board 610. Accordingly, in the circuit board of the embodiment, the metal layer 612 included in the carrier board remains at an outermost side.

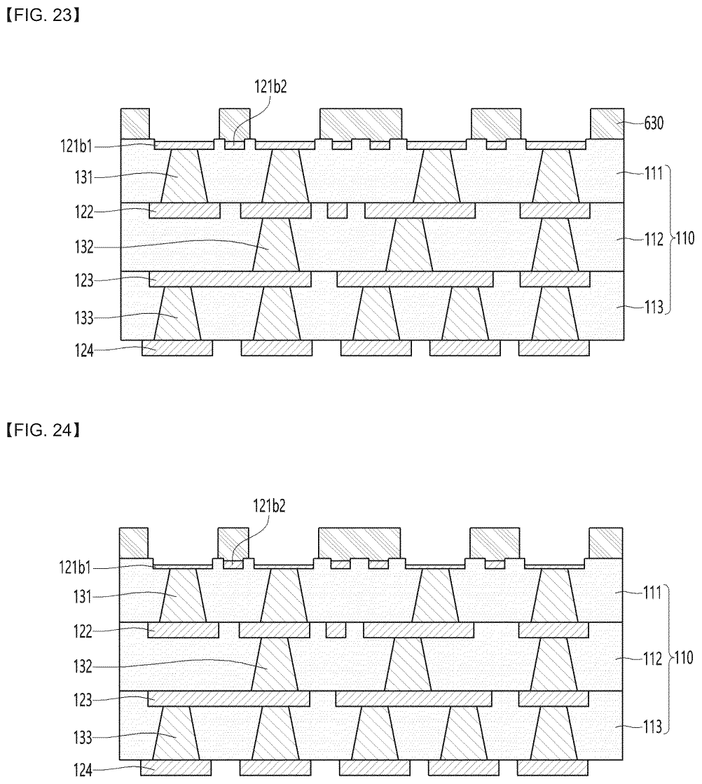

Next, referring to FIG. 22, the embodiment may perform a process of etching the metal layer 612. At this time, the embodiment may perform a process of etching the metal layer 612 so that a part of the first circuit pattern layer 121 is removed together with the metal layer 612 in a process of etching the metal layer 612. Through this, a first recess having a second depth H1 may be formed on all pattern parts of the first circuit pattern layer 121.

Next, referring to FIG. 23, the embodiment may perform a process of forming a second dry film 630. At this time, the second dry film 630 may be disposed on the first insulating layer 111. In addition, the second dry film 630 may be disposed on the trace 121b2 of the first pattern part 121b of the first circuit pattern layer 121 and the second pattern part 121a.

In addition, the second dry film 630 may not vertically overlap with the first pad 121b1 of the first pattern part 121b. For example, the second dry film 630 may include an opening that vertically overlaps with the first pad 121b1 of the first pattern part 121b.

Next, as illustrated in FIG. 25, the embodiment may perform a process of additionally etching the first pad 121b1 of the first pattern part 121b exposed through the opening of the second dry film 630. Accordingly, the first pad 121b1 of the first pattern part 121b may have a first recess 121b1R formed with a depth H2 greater than a depth H1 of the trace 121b2 of the first pad 121b1 and the second recess 121b2R and the third recess 121aR formed on the second pattern part 121a.

Next, the embodiment may perform a process of forming the first protective layer 141 and the second protective layer 142.

The embodiment can improve electrical reliability and physical reliability of a circuit board and a semiconductor package including the same.

The circuit board of the embodiment includes a first insulating layer, a first circuit pattern layer, and a first protective layer. At this time, the first insulating layer means an outermost insulating layer among a plurality of insulating layers of the circuit board. The first circuit pattern layer means an outermost circuit pattern layer among a plurality of circuit pattern layers of the circuit board. At this time, the first circuit pattern layer has an ETS structure. For example, the first circuit pattern layer is embedded in an upper surface of the first insulating layer.

At this time, the upper surface of the first circuit pattern layer has a step difference with the upper surface of the first insulating layer. Specifically, the upper surface of the first circuit pattern layer is positioned lower than the upper surface of the first insulating layer. The first circuit pattern layer includes a fine pattern. The fine pattern may be damaged by various factors in a manufacturing process and an usage environment of the circuit board. At this time, the embodiment allows the upper surface of the first circuit pattern layer to be positioned lower than the upper surface of the first insulating layer. Accordingly, the embodiment can stably protect the first circuit pattern layer from the damage. Therefore, the embodiment can solve a peeling problem or collapse problem of the first circuit pattern layer. Through this, the embodiment can improve the physical reliability and electrical reliability of the circuit board and the semiconductor package.

Meanwhile, the first circuit pattern layer can be divided into a plurality of pattern parts according to a location. That is, the first circuit pattern layer includes a first pattern part disposed in a first region where a chip is mounted and a second pattern part disposed in a second region other than the first region. The first protective layer is not disposed on the first region. In other words, the first protective layer includes a first opening that vertically overlaps the first region as a whole.

At this time, the first pattern part includes a first pad and a trace that second pad that vertically overlaps the second opening. At this time, the upper surface of the first pad can have a step difference from the upper surface of the trace and the upper surface of the second pad. That is, the upper surface of the first pad may be positioned lower than the upper surface of the trace and the upper surface of the second pad. In other words, a first recess may be formed on the upper surface of the first pad, a second recess may be formed on the upper surface of the trace, and a third recess may be formed on the upper surface of the second pad. In addition, a depth of the first recess may be greater than each of depths of the second recess and the third recess.

At this time, the first pad is a mounting pad on which a chip is mounted, and a connecting part such as solder is disposed on the upper surface of the first pad. At this time, the first protective layer is not disposed on the first region where the first pad is disposed, and thus overflow of the connecting part may occur. Accordingly, the embodiment allows the upper surface of the first pad to be positioned lower than the trace and the upper surface of the second pad, thereby securing a space for arranging the connecting part without increasing the overall thickness of the circuit board.

Accordingly, the embodiment can prevent diffusion of the connecting part and solve the circuit short problem caused by diffusion of the connecting part.

Meanwhile, the first circuit pattern layer in the embodiment includes a first pad, which is a dummy pattern, and a bonding pattern. In addition, a chip can be attached to the first pad. In addition, the bonding pattern can be connected to the chip through a connecting member such as a wire. At this time, a first recess is formed on the first pad, and a second recess is formed on the bonding pattern. In addition, a depth of the first recess can be greater than a depth of the second recess. The first recess can function as a cavity into which the chip is inserted.

Accordingly, the embodiment can lower a height at which the chip is disposed by a depth of the first recess. Therefore, the embodiment can reduce the overall thickness of the circuit board and the semiconductor package.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. A circuit board comprising:
an insulating layer including an upper surface and a lower surface, and having a recess concave from the upper surface toward the lower surface;
a circuit pattern layer disposed in the recess of the insulating layer; and
a protective layer disposed on the circuit pattern layer,
wherein the circuit pattern layer includes a first electrode and a second electrode having different thicknesses and not in contact with the protective layer, and
wherein the first electrode and the second electrode overlap each other along a horizontal direction.

12. The circuit board of claim 11, wherein a thickness of the first electrode is smaller than a thickness of the second electrode.

13. The circuit board of claim 11,
wherein a height of an upper surface of the first electrode is different from a height of an upper surface of the second electrode.

14. The circuit board of claim 12, wherein the circuit pattern layer includes a third electrode overlapping the first electrode and the second electrode along the horizontal direction, and
wherein the thickness of the first electrode is different from a thickness of the third electrode.

15. The circuit board of claim 12, wherein the thickness of the first electrode is smaller than the thickness of the third electrode.

16. The circuit board of claim 14, wherein a height of the upper surface of the first electrode is different from a height of an upper surface of the third electrode.

17. The circuit board of claim 16, wherein the upper surface of the first electrode is positioned lower than each of the upper surface of the second electrode and the upper surface of the third electrode.

18. The circuit board of claim 14, wherein the thickness of the second electrode or the height of the upper surface of the second electrode is same as the thickness of the third electrode or the height of the upper surface of the third electrode.

19. The circuit board of claim 14, wherein the thickness of the second electrode or the height of the upper surface of the second electrode is different from the thickness of the third electrode or the height of the upper surface of the third electrode, and
wherein a vertical distance from the upper surface of the second electrode to the upper surface of the third electrode is smaller than a vertical distance from the upper surface of the first electrode to the upper surface of the second electrode, and a vertical distance from the upper surface of the first electrode to the upper surface of the third electrode.

20. The circuit board of claim 14, wherein the vertical distance from the upper surface of the insulating layer to the upper surface of the second electrode or the upper surface of the third electrode satisfies a range of 2 um to 5 um.

21. The circuit board of claim 14, wherein the vertical distance from the upper surface of the insulating layer to the upper surface of the first electrode satisfies a range of 5 um to 18 um.

22. The circuit board of claim 14, wherein the first electrode is a first pad on which a terminal of a semiconductor device is mounted,
wherein the second electrode is a trace connected to at least one of the first electrode and the third electrode, and
wherein the third electrode is a second pad connected to an external substrate.

23. The circuit board of claim 14, wherein the first electrode is a first pad of a dummy electrode to which a semiconductor device is attached,
wherein the second electrode is a bonding electrode connected to a terminal of the semiconductor device attached to the first electrode, and
wherein the third electrode is a second pad connected to an external substrate.

24. The circuit board of claim 14, wherein a width in the horizontal direction of the first electrode is larger than a width in the horizontal direction of the second electrode, and
wherein a width in the horizontal direction of the third electrode is greater than the width in the horizontal direction of each of the first electrode and the second electrode.

25. The circuit board of claim 14, wherein the lower surface of the first electrode, the lower surface of the second electrode, and the lower surface of the third electrode are located on the same plane.

26. The circuit board of claim 14, wherein the protective layer includes an opening overlapping the first to third electrodes along a vertical direction.

27. The circuit board of claim 26, wherein the opening of the protective layer includes a first opening, and
wherein the first opening includes a first portion overlapping the first electrode along the vertical direction, and a second portion overlapping the second electrode along the vertical direction.

28. The circuit board of claim 27, wherein the first opening includes a third portion connected to the first portion and the second portion and overlapping with a spaced region between the first electrode and the second electrode along the vertical direction.

29. The circuit board of claim 28, wherein the first electrode includes a plurality of first electrode patterns spaced apart from each other along the horizontal direction,
wherein the second electrode includes a plurality of second electrode patterns spaced apart from each other along the horizontal direction, and
wherein the plurality of first electrode patterns and the plurality of second electrode patterns overlap with a same first opening along the vertical direction.

30. The circuit board of claim 26, wherein the opening of the protective layer includes a second opening overlapping with a portion of the second electrode along the vertical direction.
